(19) United States
(12) Patent Application Publication
(10) Pub. No.: US 2026/0330103 A1
(43) Pub. Date: Oct. 22, 2026

(54) GENERATING TELEMETRY SIMULATIONS FOR DATACENTER OPERATIONS

(71) Applicant: Nvidia Corporation, Santa Clara, CA (US)

(72) Inventors: Siddha Ganju, San Jose, CA (US); Elad Mentovich, Tel Aviv (IL)

(21) Appl. No.: 19/185,688

(22) Filed: Apr. 22, 2025

(51) Int. Cl. G06F 30/27

(52) U.S. Cl. CPC G06F 30/27

(57) ABSTRACT

Approaches presented herein provide for simulations of real-world actions to be performed in a complex computing environment, such as a datacenter. A digital twin of a datacenter can be generated, which may include a set of 3D models of functional and interconnected components, and a set of configurations can be generated that represent the state of the datacenter at different times. In order to run an accurate simulation, the appropriate configuration can be loaded for the physical digital twin to represent the state of the datacenter at a specific point in time. A workflow can be identified that represents the jobs that will likely be running at that point in time, and those jobs can be performed in the simulation. A trained language model can be used to run queries to obtain information about the simulated operations in the datacenter. This may include, for example, asking about the best time to run a job, the best time to perform maintenance, an appropriate time to perform an update or installation, or an improved configuration that can be used.

### TECHNICAL FIELD

This disclosure relates to the simulation of computing operations, and in at least one embodiment relates to a simulation of real world actions to be performed in a complex computing environment, such as a datacenter or server farm.

### BACKGROUND

As an increasing amount and variety of complex operations are being performed on increasingly large and varied datasets, computing environments such as datacenters and server farms are also becoming increasingly complex. The increasing complexity of these environments makes manually maintaining and optimizing the computing, networking, and other resources in those environments more difficult and costly, with an increased risk of human error. Further, prior approaches to manually performing maintenance often require specific resources to be turned on or off, or otherwise modified, before maintenance can begin. Due to the increasing complexity, however, it can be difficult to identify all the resources that may need to have a power state or connectivity changed, and ensure that those changes are implemented properly, and then returned to an appropriate state after maintenance has been performed.

### BRIEF DESCRIPTION OF THE DRAWINGS

Various embodiments in accordance with the present disclosure will be described with reference to the drawings, in which:

FIG. 1A illustrates an example datacenter system architecture in which aspects of various embodiments can be implemented, according to at least one embodiment.

FIG. 1B illustrates an example layout of components in a datacenter, according to at least one embodiment.

FIG. 2 illustrates an example system that can be used to generate a digital twin of a datacenter or other complex computing environment, according to at least one embodiment.

FIG. 3 illustrates an example system for simulating a datacenter and allowing use of one or more language models to query information about the simulation, according to at least one embodiment;

FIG. 4A illustrates an example process that can be performed to fine-tune models, useful in simulation, on real world data, according to at least one embodiment.

FIG. 4B illustrates an example process that can be performed to simulate operation of a datacenter and apply results of the simulation to real world operation of a datacenter, according to at least one embodiment.

FIG. 5 illustrates an example datacenter system, according to at least one embodiment;

FIG. 6 is a block diagram illustrating a computer system, according to at least one embodiment;

FIG. 7 is a block diagram illustrating a computer system, according to at least one embodiment;

FIG. 8 illustrates components of an example computing system, according to one or more embodiments.

FIG. 9 illustrates an example enterprise AI system that can be used to perform aspects of one or more embodiments.

FIG. 10 is an example data flow diagram for an advanced computing pipeline, in accordance with at least one embodiment.

FIG. 11 is a system diagram for an example system for training, adapting, instantiating and deploying machine learning models in an advanced computing pipeline, in accordance with at least one embodiment.

FIGS. 12A and 12B illustrate a data flow diagram for a process to train a machine learning model, as well as client-server architecture to enhance annotation tools with pre-trained annotation models, in accordance with at least one embodiment.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Approaches in accordance with various illustrative embodiments can provide for the simulation of operations—such as may relate to real world actions—to be performed in various computing environments, such as datacenters, that include a number of active, connected components. A digital twin of a physical datacenter can be generated, such as by using a simulation environment like Omniverse from NVIDIA Corporation. A set of configurations can be generated that each represent the state of the datacenter at a respective time, including information about the software running on each device, the number and configuration of components, and the libraries that are loaded, among other such options. In order to run an accurate simulation, the appropriate configuration can be loaded for the physical digital twin to represent the state of the datacenter at a current or future point (or period) in time. A workflow can also be identified that represents the jobs that will (or could) be running at that point in time. For many jobs there will be benchmarks that can be used to anticipate the load, including traffic and processing needs over a period of time. The simulation can then be performed, using the configuration and workflow data, to provide an accurate digital representation of the datacenter in operation at the target point in time. A trained language model (or other such mechanism, as may be script based) can be used to run queries to obtain information about the simulated datacenter. This may include, for example, asking about the best time to run a job, the best time to perform maintenance, an appropriate time to perform an update or installation, or an improved configuration that can be used. An LLM can also receive a prompt to ask whether the running of a particular job can be optimized, or optimized based on specific criteria or limits. Such functionality can be particularly beneficial for AI-related jobs with large anticipated workloads, as well as for use cases relating to robotics or automotive applications.

Variations of this and other such functionality can be used as well within the scope of the various embodiments as would be apparent to one of ordinary skill in the art in light of the teachings and suggestions contained herein.

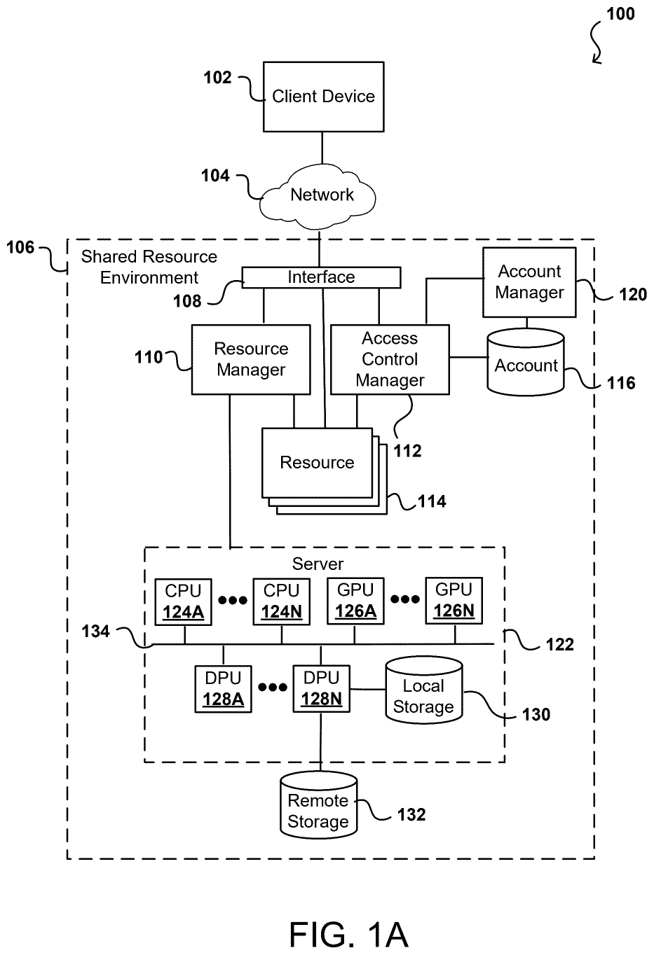

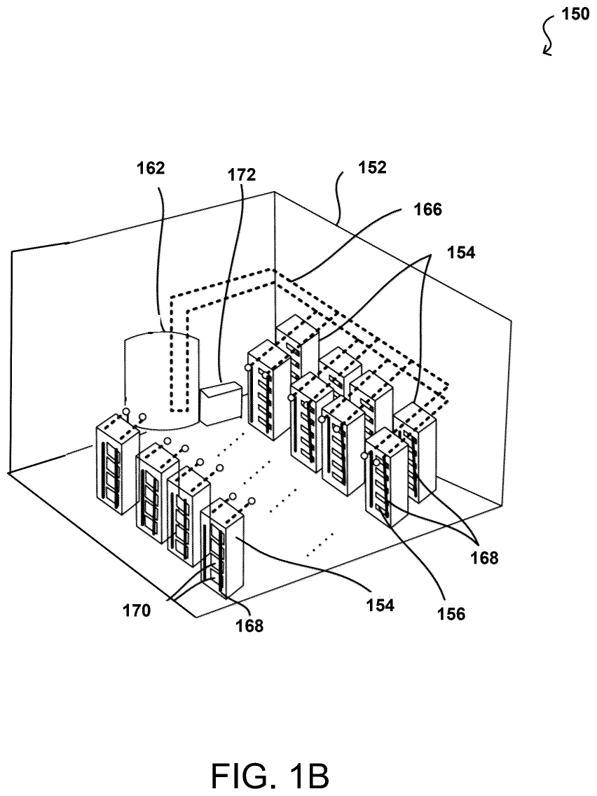

Environments such as datacenters can be used to perform various computing operations on behalf of a number of different entities, such as by using a pool of available resource capacity. FIG. 1A illustrates an example of one such architecture 100 that can be used in accordance with at least one embodiment. In this example, a user is able to use a client device 102 to submit one or more requests to access one or more resources, or to perform a task using one or more resources, among other such options. Such a request can be submitted over at least one network 104, such as the Internet or a cellular network, and received to an interface, address, or endpoint in a shared resource environment 106. The request can be received to an interface, such as an application programming interface (API) of an interface layer 108, for example, which may include other networking devices as well, as may include routers, network switches (e.g., an NV-Switch or Spectrum-X switch), load balancers, and the like. In this example, a request from a client device 102 may first need to be analyzed to determine whether the client device, user, or other entity associated with the request has access to one or more resources to be used to process the request, as well as to determine whether the type of access permitted allows for performance of the requested operation.

In this example, information for the request can be directed to an access control manager 112, or other such component, system, or service. The access control manager 112 can perform various tasks to determine and/or manage access to a set of shared resources 114, such as to extract relevant information from a received request and compare, by an account manager 120 or other such system or service, information for the request against information in an account repository 116 or other such location. If it is determined that the request is associated with a valid account, that account information can be used to determine the type of access permissible to perform one or more operations associated with the request. In some embodiments, an access control manager 112 may work with a resource manager 110 to determine a specific instance of a type of resource 114 to be used to perform an operation with respect to the request, whereas the resource manager 110 can perform other types of operations as needed, such as to allocate additional capacity of a type of resource, launch a new compute instance, or perform another such task associated with the request.

In many instances, a request that involves a number of operations to be performed may have those operations, or portions of those operations, distributed across a set of processing resources. This may include distribution across a number of physical compute resources, such as a set of shared servers, and/or may include multiple processing resources (physical or virtual) within a given physical resource. As an example, FIG. 1A illustrates example components that may be found within a given server 122 that may be allocated to perform one or more processing tasks with respect to a request. The server 122, in this instance, is illustrated to contain different types of processing units, including one or more central processing units (CPUs) 124A-N, one or more graphics processing units (GPUs) 126A-N, and one or more data processing units 128A-N, as may be interconnected using at least one internal bus 134. At least the DPUs 128A-N in this example may be connected to local storage 130 in the server, as well as at least one remote storage instance 132 that may be external to the server but within the shared resource environment 106. CPUs 124A-N are often used for tasks such as single threaded user applications, and GPUs 126A-N are often used to perform multiple small but related operations in parallel. DPUs can be used to offload processing tasks from these CPUs and GPUs that may not optimally be performed on these processing units, as may related to heterogeneous data-centric processing tasks that can benefit from a different type of accelerated processing. A DPU is a programmable processor or system-on-chip, which combines one or more multi-core, high-performance CPUs, a set of acceleration engines that can offload and improve performance for data-centric tasks, and one or more high-performance interfaces capable of parsing, processing, and efficiently transferring data at high speeds. A DPU can be used as a stand-alone embedded processor, or can be incorporated into a smart network interface card (SmartNIC) in a server, among other such options.

In at least one embodiment, a datacenter 150 in FIG. 1B may include one or more rooms 152 having racks 154 and auxiliary equipment to house one or more servers 170 on one or more server trays, as well as graphics processing units (GPUs) 156 and other such components. In at least one embodiment, a datacenter 150 can be supported by a cooling tower located external to the datacenter 150. A cooling tower can dissipate heat from within a datacenter 150 by acting on a primary cooling loop 166. In at least one embodiment, a cooling distribution unit (CDU) 162 is used between a primary cooling loop 166 and a secondary cooling loop, or other such heat removal mechanism. There may be cooling manifolds 168 used for individual server racks, for example, and a heat exchanger 172 or other temperature management system used to provide additional cooling and/or temperature management. Proper maintenance of such a datacenter involves not only maintenance of the computing resources, but also components and systems related to networking, power, cooling, and other such aspects. In many instances, maintenance of any one of these types of devices or systems may involve modification, at least temporarily, of one or more of these other types of devices or systems.

As mentioned, proper maintenance can be crucial in such a complex computing environment to prevent outages and keep everything running smoothly, in order to prevent data loss or a need to reperform long and complex operations, among other such undesirable outcomes. There are various problems that can arise before and during such maintenance, as may include power issues for power-hungry datacenters, where any significant disruptions in operation can potentially be catastrophic. Power failures, uninterruptable power supply (UPS) malfunctions, or problems with backup generators can all lead to undesirable and/or unacceptable downtime. There may be various other types of problems as may relate to cooling, as datacenters generate a lot of heat, and it can be essential to have efficient cooling systems to maintain optimal temperatures, or at least temperatures within target operational ranges. Ineffective cooling systems or clogged vents can lead to overheating and equipment failure. There may also be various network connectivity issues which can severely impact a datacenter's functionality. Problems such as disorganized cabling, outdated hardware, or software incompatibilities can all cause disruptions. There can be problems related to buildup of dust or debris, which if allowed to accumulate over time may obstruct airflow and increase the risk of overheating or fires. As mentioned, there is also the risk of human error, as accidental mistakes during maintenance procedures can damage equipment or cause outages. Proper training and clear protocols can help minimize this risk. There are various other potential problems that can require and/or occur during datacenter maintenance. Having a comprehensive maintenance plan and qualified staff can help datacenter operators to minimize these and other such risks, and keep their facilities running smoothly.

Approaches in accordance with various embodiments can perform highly accurate simulations of datacenters and other such complex computing environments, in order to help generate and update a comprehensive maintenance plan, as well as plans for optimization and modernization, among other such aspects. Such a simulation can also help to generate telemetry data in advance of performing a job, in order to predict how and when to best perform a job. As discussed in more detail elsewhere herein, a digital twin of a datacenter can be generated in a simulation environment, such as may be provided using Omniverse from NVIDIA Corporation. A digital twin can include any relevant components that may be considered in such a plan, and can include connections, cooling, networking, and other such aspects as connected to and/or utilized by those resources. In at least some embodiments, digital datacenters may be generated to include specific combinations and/or configurations of resources that may not correspond to an existing or actual datacenter, where any simulation data obtained from such an environment may be used to train an artificial intelligence (AI) model with respect to such an environment.

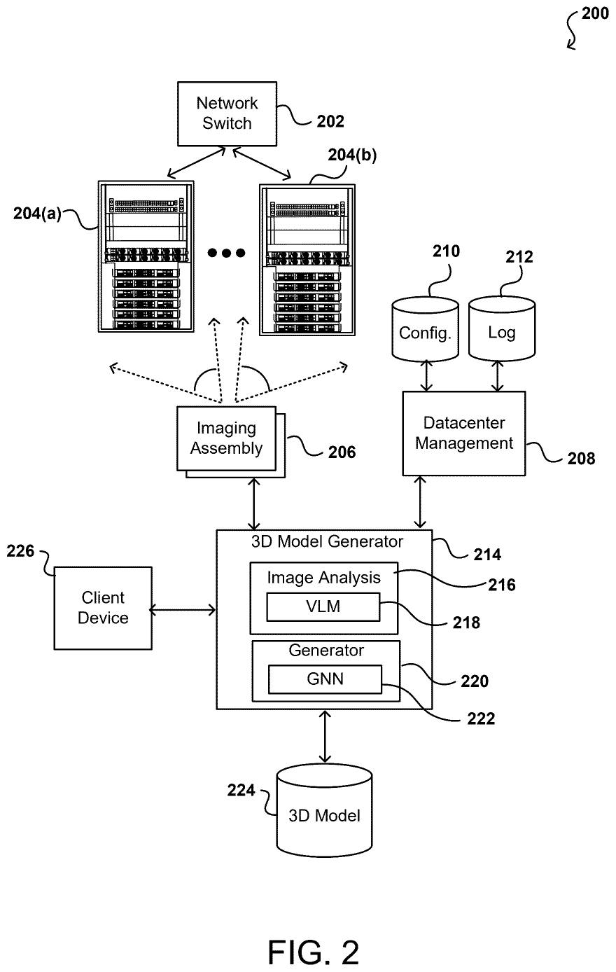

FIG. 2 illustrates an example system 200 that can be used to generate a digital twin of a complex computing environment in accordance with at least one embodiment. In this example, information can be obtained from at least one datacenter management system 208, which stores information about the number, type, location, configuration, and other such aspects about the components in a datacenter, as may be stored in one or more configuration databases 210 and/or log databases 212. This information can be used with existing 3D models or other representations of the types of components or devices in a datacenter. In this example system 200, image data can also be collected for a datacenter that can be used to improve the accuracy of a digital twin to be generated for a datacenter. This can include using one or more imaging assemblies 206, such as mounted cameras, cameras on portable computing devices, cameras or imaging sensors on one or more robotic assemblies, LiDAR systems, and the like, to capture image and/or distance information about the components in the datacenter. The image information can provide information not only about the exact placement and orientation of various components, but also can serve as a check on whether all devices have accurately been accounted for, including cabling, cooling vents, and other such aspects.

The device, configuration, placement, and other such information can be provided as input to a three-dimensional (3D) model generator 214, which can attempt to use this information to generate an accurate digital twin of the datacenter. This can include, for example, generating a 3D model that includes all the relevant servers 204(a)-(b), racks, cooling systems, and network components (e.g., network switches 202 and cabling) in the correct positions and orientations. The model may or may not include visually accurate representations, but can at least include 3D geometric shapes that represent the approximate bounds and placement of various components. During a simulation, a user can zoom in on specific devices (or groups of devices) in the digital twin to obtain information about specific models, connections, configurations, and so on.

A 3D model generator 214 in this example can include an image analysis module 216 that can take the image (or distance, point cloud, etc.) data captured for a target datacenter and analyze the data to attempt to determine the types, locations, and orientations of objects located in the datacenter, as well as any connections, cabling, tubing, cords, or other such accessories or connectors used with those objects. This may include using one or more computer vision algorithms, or as in this example may include at least one vision language model (VLM) 218 that is fine-tuned on datacenters, and similar complex computing environments, to provide a language-based description of the datacenter. The output of the image analysis module 216 can then include, for example a list or set of recognized devices, as well as identifying information for those devices, placement and orientation information, connection information, and the like. This information can be input into a representation generator 220, along with the configuration information obtained from the datacenter management system 208. A generative neural network (GNN) 222 or other such component can then be sued to perform the generation. The generated model can then be stored to a 3D model database 224 or provided for presentation or use on a client device 226, among other such options.

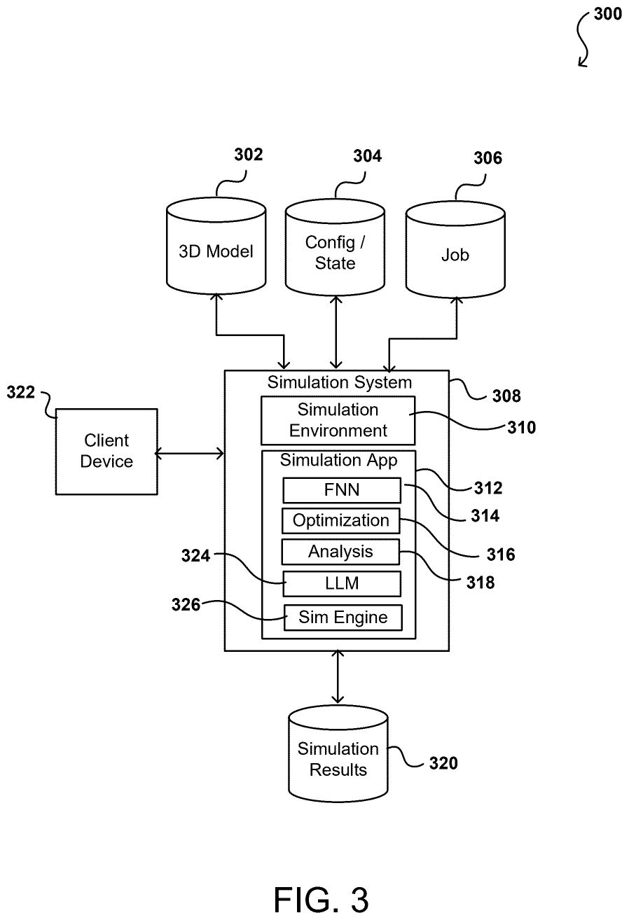

Once a 3D model 224, or digital twin, of a datacenter is generated, that model can be used to perform a simulation of that datacenter in operation. FIG. 3 illustrates an example system 300 that can be used to simulate a datacenter in operation according to at least one embodiment. In this example, a simulation system 308 can operate a simulation environment 310, such as an Omniverse environment from NVIDIA Corporation. The simulation system 308 can include one or more servers, for example, or one or more physical or virtual processors (e.g., CPUs, GPUs, or DPUs) on a single server, among other such options. The simulation system 308 can load the 3D model of a datacenter from a 3D model repository 302, for example, and can load configuration and/or state information from a configuration and/or state repository 304 to be used with the 3D model in the simulation. The 3D model can provide information such as the layout of various objects in the datacenter, while the configuration and/or state data can indicate which connections are active, which devices are operational, and the like. The state data can also specify operational conditions as well, such as temperatures at various locations, amount of active cooling, and so forth. By loading the 3D model and applying the relevant configuration and/or state data, the simulation environment 310 can provide an operational digital twin of a specific datacenter.

In this example there is a separate simulation application 312 that runs the actual simulation using the digital twin of a datacenter in the simulation environment 310. It should be understood, however, that in some embodiments the simulation environment may be provided using the same simulation application 312. In this example, the simulation application 312 may load information for one or more jobs to be simulated from a job database 306. Certain jobs, such as AI-related training or inferencing jobs, may be long-running jobs with very predictable workloads. The simulation application 312 can cause one or more jobs to be simulated in the simulation environment 310. Various types of data or metrics about the simulation can be collected, as may be analyzed using one or more analysis modules 318 to generate results, statistics, telemetry data, health data, or other such information. These results can be stored to a simulation results log 320 or provided for review on a client device 322, among other such options. An optimization module 316 of the simulation application 312 can also attempt to identify any optimizations that may be able to be made to improve on the performance of the job. This may include, for example, the ability to reduce required resource capacity, use cheaper resource capacity, improve latency, or reduce traffic congestion, among other potential optimizations. Any optimizations identified during simulation can potentially be applied to the actual operation of the datacenter when that job, or a similar job, is to be performed.

In such a simulation environment 310, synthetic data can be generated about the behavior of a simulated datacenter as well. This may include the generation of synthetic performance data for various hardware and/or software components. In at least one embodiment, there may be software (e.g., Prometheus or Graphana) executing in, or with respect to, the simulation environment 310 that can be used to collect health statistics about these simulated components, as well as information about the infrastructure and operation during the simulation. Such software can also be used to attempt to identify trends in the data obtained during the simulation, as may be obtained for both physics-and real world-aware modeling. In many situations, a datacenter management team will have a set of default actions and tools to be used for debugging and other such troubleshooting, which the team may have built up from their experience dealing with many different types of issues. The simulation of a datacenter, or other complex computing environment, can be used to generate a library of environments and associated actions that can be used for these and other types of issues.

In one example use of a simulation, it may be determined at runtime that an actual, physical maintenance event is upcoming with respect to a datacenter. In advance of this maintenance event, a datacenter simulation can be loaded into the simulation environment with information corresponding to an accurate, up-to-date digital twin of the datacenter. This may include current state, load, configuration, and other such information for the simulation to generate an accurate simulation. Once an accurate simulation is available, there may be various maintenance-related actions simulated to determine potential outcomes, preferences, optimizations, and the like. For example, there may be various real-world actions that can be simulated in this environment that may be performed before, during, or after a maintenance event, such as may relate to bringing down a hot aisle temperature or collecting health statistics, among other such options. Such simulations can be used to determine optimal temperatures, adjustments in cooling, adjustment of backup resources, and the like.

In at least some embodiments, there may also be new telemetry features added based at least in part on the simulation. In one example, one or more large language models (LLMs) 324 can be used to query the simulation environment 310 for various types of information about the simulation. An LLM 324 can then use such information to attempt to build out additional action sets. An LLM 324 to be used can first be trained generally on computing environments, and then can be fine-tuned on relevant operation and maintenance-related training data to improve accuracy and efficiency, as may be specific to tasks such as datacenter maintenance. A simulation environment 310 can be used to simulate operation of a datacenter for certain jobs, for example, and can generate synthetic data to build out various test experiments. These experiments can be used to obtain data useful in optimizing or at least improving an accuracy of these simulated environments, as well as actions performed in those environments. In at least one embodiment, personalization can be added at the datacenter level, as well as potentially the user level and other such levels. One or more localized adaptations can be performed that can be controlled by, for example, IT management software that interfaces with the simulation environment 310.

There can also be actions performed in the real world, outside of the simulation environment 310. Relevant data, as may be generated from real-time statistics and diagnostics, can be collected from a physical datacenter during operation and/or maintenance. Such data can contain information about the health of a computing or processing device or system, for example, as may relate to a central processing unit (CPU) or graphics processing unit (GPU). The information may also relate to a health or operational state of various optical or networking components, workflows running and performance given by machines, scheduled maintenance, prior maintenance, and upcoming replacements, among other such information. The data can be analyzed to determine, for example, whether there are any important trends that can be leveraged to add to a library of environments and associated actions. In some embodiments, this information can be added to the configuration and/or state repository 304 for a specific datacenter, which can then help to generate more accurate simulations.

A digital datacenter twin, or similar model of a complex computing environment, can be defined in a file format that is able to be understood by a simulation application 312. Such a file can include various instances of geometry, as may include three-dimensional (3D) models, meshes, or other such representations of objects, terrain, and boundaries useful for performing 3D simulations. The file may also include any relevant rules or properties that are to be used for the simulation. This can include, for example, physical laws, material properties, or behavioral parameters for entities within the environment, such as those used in physics simulations, game engines, or agent-based models. Some environments might be procedurally generated based on pre-defined rules, eliminating the need for a separate file.

During a loading process, a simulation application 312 can read an environment file and parse the data. Depending at least in part on the complexity, the application might create objects, such as by converting 3D models into in-engine objects with proper textures and collision detection. The software might also set up or apply one or more rules, as may be used to establish the physical laws, material properties, and/or behavioral parameters within the simulation. The software can also attempt to optimize for performance, such as by attempting to simplify the environment or pre-calculate certain aspects to ensure smooth simulation runtime.

During an initialization phase, a simulation environment 310 can be loaded or provided, and a simulation application 312 can set the initial state of a simulation to be performed within the simulation environment. This may involve, in at least one embodiment, positioning objects within the environment based on, for example, the file or user input. The software can also set various initial conditions, as may include assigning initial values to any relevant variables (e.g., the velocity of objects or an initial temperature) within the simulation. After the simulation environment 308 has loaded and initialization has completed, the simulation can be started. At this point, a simulation engine 326 can take over to perform tasks such as to start processing the simulation logic based on the defined rules and properties. This may involve use of an operational loop that iterates through a sequence of time steps in at least one embodiment. Data about the simulation can be generated and/or collected, and results of the simulation can be written to a simulation results log 320 or otherwise processed as discussed in more detail elsewhere herein.

In one example, an entire datacenter can be represented in a digital twin form in a simulation environment 310. This digital twin can be loaded and used for various simulations before similar actions are performed with respect to the real datacenter. The datacenter can be accurate down to small details, as may relate to the exact specifications for the wiring, cabling, networking, available processing capacity, jobs running on each processing unit, and the like. Such a digital twin can be used to generate multiple simulations with different configurations and state information, for example, as may relate to a current state and/or multiple potential future operational states. In one such simulation, it can be desired to simulate the use of specific versions of software, operating systems, and firmware, as well as the loading of specific libraries and availability of one or more datasets. This information can be specified in a configuration file, for example, that can be loaded into a simulation of a datacenter. Once a simulation is running with these characteristics, versions, and so forth, health checks or other testing can be performed. Currently, an IT team would need to generate and run a number of scripts to perform a health check on a physical datacenter. When performing a simulation, however, the health data to be obtained and/or health checks to be performed can be specified ahead of time, or even during the simulation, and the health data can be generated automatically through the simulation. This data can be generated without the need for manual scripting or execution separate from the simulation. In at least one embodiment, there may be a set of health statistics automatically generated such that the user does not need to specify anything specific unless desired. Such an approach can be advantageous for use with a cluster of processing devices used to perform an AI-related task, where the job is well understood and the load over time can be accurately modeled in the simulation. The health and telemetry data can be provided not only at the datacenter level, but also at the AI cluster level. The ability to submit queries against the simulation using an LLM 324 can also provide for new types of data to be obtained, or optimizations made, that may not otherwise have been possible. In at least one embodiment, there may be multiple configuration files generated that can be stored to a configuration and/or state repository 304, with each representing a different configuration or operational state of a datacenter, or a snapshot of the datacenter at a particular point in time. These configuration files can then be loaded and used for simulation as appropriate, such as to perform additional testing or training data generation.

As mentioned, a graphical user interface (GUI) may be provided that may be presented via a client device 322, for example, that may allow a user to obtain information about the digital twin during a simulation. A user may be able to access a realistic 3D view of the datacenter, and may be able to move a virtual camera through that 3D view in order to be able to access specific components or sets of components. A user may be able to zoom in on the connectors of a specific device, such as a server, in order to view current or available connections. A user may also be able to select a specific object, such as a representation of a specific server, to obtain information about that server. This may include, for example, current configuration, software, firmware, OS, or other configuration, as well as connections, load, installed hardware, and other relevant information. A user may also be able to make at least some modifications to an individual component, such as to change a configuration, simulate a different set of installed software, reboot or restart, or perform other such simulations. In some embodiments, a user can virtually “drag” a connection from one port or device to another, disconnect or unplug certain components, and perform similar such actions. Information for a cable, which may include a date and time of last installation in addition to information such as manufacturer, serial number, and capacity, may then be updated to reflect the change in connectivity in the configuration file. Any checks or changes can also be used to update any health, preventative maintenance, or other information stored for the relevant components in the configuration file. The configuration file can thus be maintained as an exact functional replica of a specific datacenter at a point in time where all those configuration values are accurate.

In at least one embodiment, a flow can also be executed on top of the accurate digital twin. There can be a number of jobs that are to be running, and these jobs can be placed in various locations to be performed using different resources, or portions of resource capacity. There is not then just a single, static configuration file in many instances. There can be various configuration files for different points in time, or a configuration file may include options or ranges that may result in different values or options at different points in time. A configuration file may include information about how data and processing is moving or changing within a datacenter over a period of time. A user can then use the GUI to fast forward or rewind the simulation to specific points in time, in order to obtain health metrics or perform testing according to those points in time. Such information can also be used to determine or identify points in time where it may make sense to perform various operations. For example, there may be a requisition received to install a new component. The simulation can be analyzed at various points in time, or over a period of time, to determine an “optimal” state or point in time to perform that action. For example, the optimal time might be determined to occur right after a long-running job has completed. This information can be provided as an output of the simulation, and used by a maintenance team to determine when (and where, etc.) to perform the corresponding maintenance task (e.g., installation). The simulation can also help identify tasks that should be performed before the maintenance task, such as to disconnect one or more cables, power down one or more devices, and so on. The simulation can also attempt to determine whether the installation is reasonable, or whether a different action might better accomplish the desired goal. For example, instead of installing an additional server, it might be determined that it would be better from a resource management standpoint to transition some load between existing servers, or change the types of servers used to process certain workloads, in order to free up the necessary capacity using existing resources. An LLM 324 can allow a user to submit queries about the simulation as well, which can help to determine information about the potential installation, better times or ways to perform the installation, and so on.

Some simulations may be performed for varying workloads as well. In some embodiments, a resource manager or similar component can collect data from the physical datacenter, and that data can be fed into the simulation environment, in order to attempt to replicate the current state of the datacenter as accurately as possible. There may be some simulations to be performed, however, where the job is not currently running or there is no prior job data available. For these types of jobs, there may be benchmarks or other information that can be used to attempt to predict the amount of memory, compute capacity, networking bandwidth, power consumption, cooling, and other such metrics that will be required for (or will at least likely be used for) a given job, or set of jobs. Such benchmarks may include, for example, high performance computing (HPC) benchmarks, computer vision benchmarks, or deep learning model benchmarks, among other such possibilities. Benchmark data can include observed data with respect to performance aspects such as speed or latency, processing time, and the like. In at least one embodiment, such benchmark data can be extrapolated as needed to cover jobs where there may not be sufficient data. For AI-related jobs, such extrapolation can be performed based in part upon the number of parameters of the respective model(s), along with any variance trends (such as whether the parameters vary linearly or exponentially with the number of parameters). There may be more complex workflows where such extrapolation may not provide sufficient accuracy, or may not be sufficient to model behavior. In at least one embodiment, a component such as a reinforcement agent can be trained to attempt to determine or infer requirements, and attempt to also predict whether there might be more optimized ways of processing a complex job or set of jobs. A model can be used that is fine-tuned using reinforcement learning, which provides the advantage of being able to have optimization results tested and updated in a simulated world before actually running a very expensive job in the real world, which allows the performance to be updated as much as possible through simulation, thus saving potentially significant computing time, resources, and cost in the actual datacenter. Testing through simulation also allows for the use of various combinations of processing, storage, memory, and other such resources, in order to find a beneficial combination without having to perform multiple instances of expensive, real-world testing. Such an approach can also allow for the addition or modification of resources before the job is performed, in order to right-size the datacenter before additional, less, or other capacity is needed.

An example workflow can include a sequence of tasks to be performed in training a given model. It might be the case that the datacenter has to concurrently perform rendering or simulation of data at the same time, as may be common for use cases such as those relating to automotive or robotics applications. A given simulation may simulate thousands of different scenarios, as may involve changing aspects of the computing environment, the actors, the degrees of freedom of a robot, and so forth. The data simulation can be performed before it is needed to train the model, which can be extremely difficult in at least some situations. Having a simulated datacenter that is an accurate digital twin, and knowing which jobs are to be run, allows for simulation and testing of a large number of different scenarios, and once an optimal (or at least a beneficial) solution is identified, that solution (or at least aspects of that solution) can be implemented in the physical datacenter before (or while) the jobs are being performed. The optimization can be based on various optimization factors as well, which may include compute cost, processing time, memory usage, bandwidth, and so on.

Referring again to FIG. 3, a simulation may be run using one or more pre-trained models, such as one or more foundational neural networks (FNNs) 314. A foundational model can be trained on a general set of data to provide general inferencing on a topic. These FNNs 314 may be fine-tuned for specific types of jobs, as not all datacenters or clusters of servers will run all types of jobs for which an FNN is trained. As an example, a datacenter used by a scientific laboratory may perform various high performance computing (HPC) type jobs, and thus may benefit from a model that is fine-tuned for at least HPC-type jobs. The FNNs 314 can be live models that are not fixed but are continually fine-tuned or further trained over time for use in tasks such as optimization, as may be used by an optimization module 316, or querying, as may be used in an LLM-based querying process, among other such options. In one embodiment, each optimization decision can potentially be used as additional training data to help fine-tune the model for subsequent optimizations on similar types of jobs or workflows. For AI-related jobs where the load is predictable, training optimization models on the AI data can help to fine tune the optimization process and produce highly accurate results as the traffic and load are highly predictable. Models can also be fine-tuned to take into account seasonality, periods of varying demand, and the like, which can help to plan ahead, not only with the best times to run a given job, but when to make adjustments to the capacity in a given datacenter.

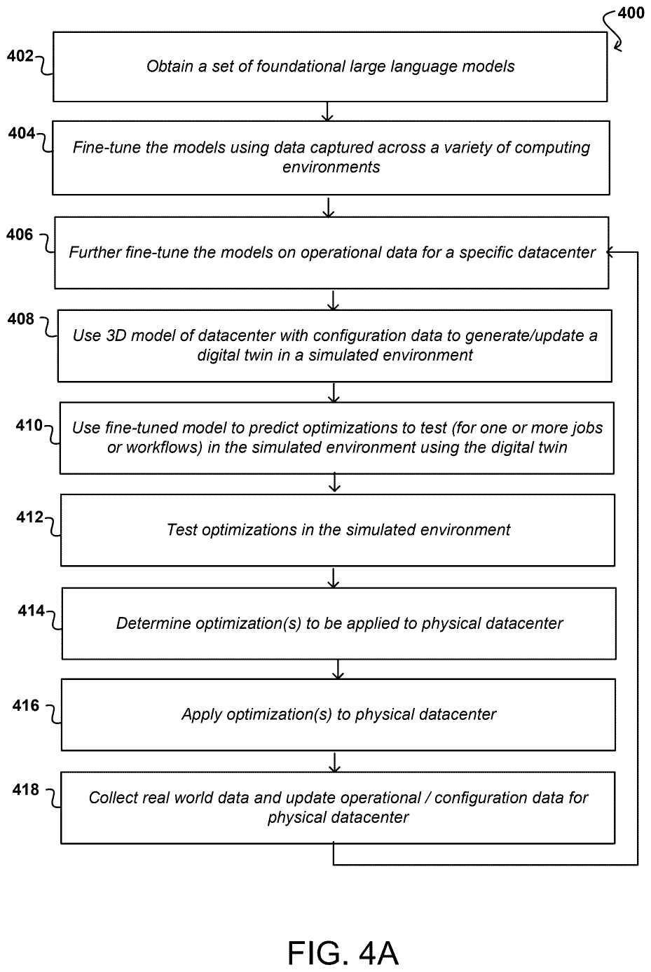

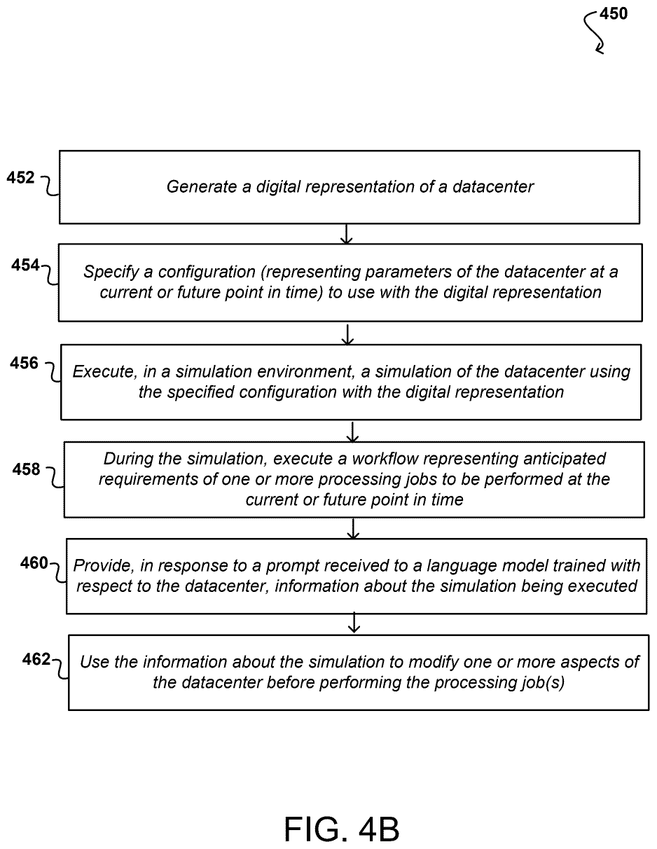

FIG. 4A illustrates an example process 400 that can be performed to fine-tune one or more AI models on a datacenter, in accordance with at least one embodiment. It should be understood that for this and other processes discussed herein that there may be additional, fewer, or alternative steps performed in similar or alternative orders, or at least partially in parallel, within the scope of the various embodiments. Further, although discussed with respect to optimizations of a datacenter, it should be understood that advantages of simulating real world operations in a complex computing environment can be obtained for various other purposes as well, as may relate to tasks such as maintenance and planning of various hardware and/or software resources, including networking, cooling, and other resources that may not be directly related to computing operations. In this example process, a set of foundational large language models (LLMs) is obtained 402. This may include, for example, one or more LLMs trained generally on language that may be relevant to the world as a whole, or at least to the world as it relates to computing operations and environments. These models, which can be highly accurate for general purpose language, can be fine-tuned 404 (or further trained) using data captured across a variety of computing environments, such as IT data generated or captured across a variety of different computing environments. Such fine-tuning can improve the accuracy, in general, of an LLM with respect to datacenter (and similar) operations. These fine-tuned models can then be used with a variety of different computing environments, allowing for querying of data, instructing of optimizations or modifications to a simulation, and so forth.

In this example, a simulation is to be performed with respect to a specific datacenter. In order to improve the accuracy of one or more of these LLMs, the LLM(s) can be further fine-tuned 406 (or further trained) using operational data captured for that specific datacenter. This may include, for example, telemetry data, configuration data, and operational data for the datacenter for at least one point in time. A simulation can then be performed or executed that can provide a digital twin of that specific datacenter. This can involve using 408 a 3D model of the datacenter that includes 3D models or representations of objects in the physical datacenter, as may include models of servers, racks, cooling system, network components, cabling, and the like. The 3D model can use configuration data for a specific datacenter at a specific point in time in order to generate an accurate digital twin of the datacenter at that time. At least one of the fine-tuned models can be used 410 with the digital twin in the simulation environment to predict optimizations that can then be tested in the simulated environment using the digital twin. The optimizations can be determined based in part on one or more jobs or workflows that are to be performed in the physical datacenter. In at least one embodiment, a fine-tuned model can obtain and/or query information about the digital twin and the job, and can infer a set of potential optimizations. At least a subset of the optimizations can then be tested 412 in the simulated environment. There might be a maximum number of optimizations allowed to be tested, or a rule to test only optimizations that are predicted to make at least a minimal improvement in one or more aspects of job performance, among other such options. In some embodiments, certain optimizations may not be allowed, such as to add more than an allowable capacity or violate certain quality of service agreements, and the like.

The optimizations can be tested using the digital twin in the simulation environment, and metrics, telemetry, or other data obtained regarding the various optimizations. It may then be determined 414 that one or more of these optimizations should be applied to the physical datacenter, and information or recommendations about these optimizations can be applied in an appropriate format. In some embodiments, at least certain types of optimizations may be made automatically without need for human interaction. One or more of the optimizations can then be applied 416 to the physical datacenter, either at the current time or at some future point in time before a corresponding job or workflow is to be performed. Real world data can then be collected 418 regarding the performance of the datacenter with the applied optimization(s), and the operational, configuration, and/or state data for the physical datacenter can be updated. This updated information can be used as updated training data for use in further fine-tuning one or more of the models, in order to provide for more accurate optimizations and inferences for future jobs with respect to the current state of the datacenter. In some embodiments, different models may be used for different types of jobs or workflows, and individual models can be fine-tuned using data relevant to those jobs or workflows. A model can also allow information about a simulation to be queried using various inputs, as may relate to language, text, image, audio, scripts, and the like. The LLMs can also be used to perform health checks or predict maintenance, among other such uses, and updates in the physical datacenter can continue to be used to update the digital twin and further fine-tune the relevant models. A fine-tuned LLM can also help a new user ask questions to better understand the datacenter and its operation. This can include, for example, requesting telemetry data about specific objects in a datacenter, as may relate to specific GPUs, switches, NICs, or other such components.

FIG. 4B illustrates another example process 450 that can be performed according to at least one embodiment. In this example process 450, a digital representation (e.g., a 3D model) of a datacenter is generated 452, where that representation includes an accurate digital recreation of the datacenter that can be used in a simulation environment. In addition to the digital representation, a configuration can be specified 454 that represents parameters of the datacenter at a current or future point in time, which is to be used for the simulation. Configuration for a current point in time may be obtained from the datacenter, while configuration for a future point in time can be inferred from the current configuration information based upon known changes, predictions, or extrapolations, among other such options. A simulation of the datacenter can then be executed 456 in a simulation environment, using the specified configuration applied to the digital representation of the datacenter. As mentioned, the simulation can be performed in a simulation environment such as is provided using Omniverse from NVIDIA Corporation. During the simulation, a workflow can be executed 458 that represents the anticipated requirements of one or more processing jobs to be performed at, or near, the current or future point in time. The workflow may be executed many different times, in sequence or in parallel, in order to test the impact of various potential optimizations or to provide various types of data, etc. In response to a prompt received to a language model that has been fine-tuned with respect to the datacenter, information can be provided 460 about the simulation being executed. This may include, for example, telemetry data for a given simulation or impacts of an applied optimization, among other types of information. The information about the simulation can then be used 462 for various purposes, such as to modify one or more aspects of the physical datacenter before performing the one or more jobs of the workflow. Such an approach allows the real world performance of one or more jobs to be optimized or tested ahead of time, for example, using a time-specific digital twin of the datacenter in a simulation environment. After sufficient training, the LLM will also be fine-tuned enough to be able to generalize to previously unseen events, at least to the extent that aspects of those events may be at least somewhat predictable. Such LLMs can be used with a simulation environment to build out actions and environments to suit datacenter operation and/or maintenance with telemetry information.

### Datacenter

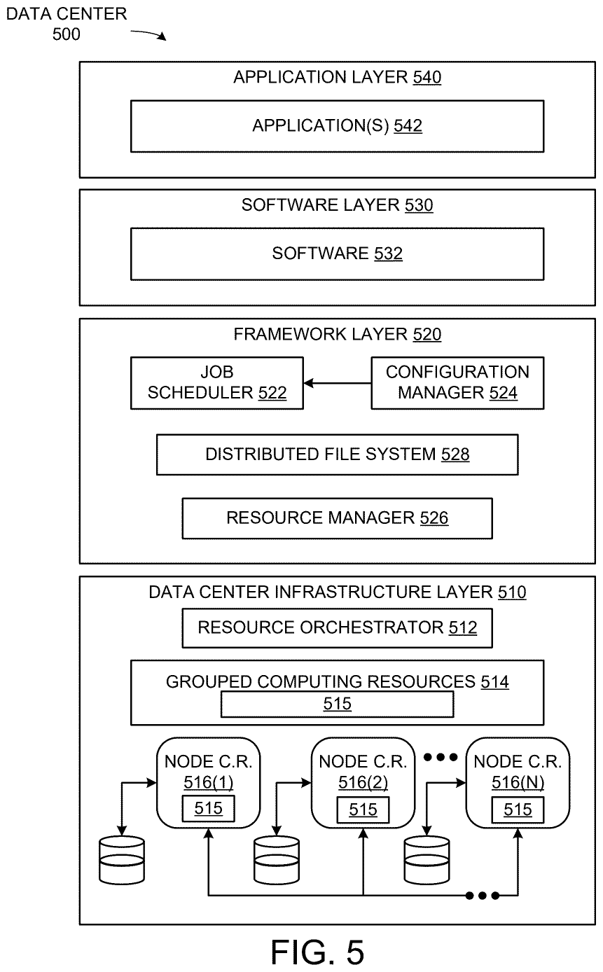

FIG. 5 illustrates the architecture of an example datacenter 500, in which at least one embodiment may be implemented. In at least one embodiment, data in this datacenter 500 includes a datacenter infrastructure layer 510, a framework layer 520, a software layer 530, and an application layer 540.

In at least one embodiment, as shown in FIG. 5, datacenter infrastructure layer 510 may include a resource orchestrator 512, grouped computing resources 514, and node computing resources (“node C.R.s”) 516(1)-516(N), where “N” represents a positive integer (which may be a different integer “N” than used in other figures). In at least one embodiment, node C.R.s 516(1)-516(N) may include, but are not limited to, any number of central processing units (“CPUs”) or other processors (including accelerators, field programmable gate arrays (FPGAs), graphics processors, etc.), memory storage devices 518(1)-518(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 516(1)-516(N) may be a server having one or more of above-mentioned computing resources.

In at least one embodiment, grouped computing resources 514 may include separate groupings of node C.R.s housed within one or more racks (not shown), or many racks housed in datacenters at various geographical locations (also not shown). In at least one embodiment, separate groupings of node C.R.s within grouped computing resources 514 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 512 may configure or otherwise control one or more node C.R.s 516(1)-516(N) and/or grouped computing resources 514. In at least one embodiment, resource orchestrator 512 may include a software design infrastructure (“SDI”) management entity for datacenter 500. In at least one embodiment, resource orchestrator 512 may include hardware, software or some combination thereof.

In at least one embodiment, as shown in FIG. 5, framework layer 520 includes a job scheduler 522, a configuration manager 524, a resource manager 526 and a distributed file system 528. In at least one embodiment, framework layer 520 may include a framework to support software 532 of software layer 530 and/or one or more application(s) 542 of application layer 540. In at least one embodiment, software 532 or application(s) 542 may respectively include web-based service software or applications, such as those provided by Amazon Web Services, Google Cloud and Microsoft Azure. In at least one embodiment, framework layer 520 may be, but is not limited to, a type of free and open-source software web application framework such as Apache Spark™ (hereinafter “Spark”) that may utilize distributed file system 528 for large-scale data processing (e.g., “big data”). In at least one embodiment, job scheduler 522 may include a Spark driver to facilitate scheduling of workloads supported by various layers of datacenter 500. In at least one embodiment, configuration manager 524 may be capable of configuring different layers such as software layer 530 and framework layer 520 including Spark and distributed file system 528 for supporting large-scale data processing. In at least one embodiment, resource manager 526 may be capable of managing clustered or grouped computing resources mapped to or allocated for support of distributed file system 528 and job scheduler 522. In at least one embodiment, clustered or grouped computing resources may include grouped computing resources 514 at datacenter infrastructure layer 510. In at least one embodiment, resource manager 526 may coordinate with resource orchestrator 512 to manage these mapped or allocated computing resources.

In at least one embodiment, software 532 included in software layer 530 may include software used by at least portions of node C.R.s 516(1)-516(N), grouped computing resources 514, and/or distributed file system 528 of framework layer 520. In at least one embodiment, one or more types of software may include, but are not limited to, Internet web page search software, e-mail virus scan software, database software, and streaming video content software.

In at least one embodiment, application(s) 542 included in application layer 540 may include one or more types of applications used by at least portions of node C.R.s 516(1)-516(N), grouped computing resources 514, and/or distributed file system 528 of framework layer 520. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 524, resource manager 526, and resource orchestrator 512 may implement any number and type of self-modifying actions based on any amount and type of data acquired in any technically feasible fashion. In at least one embodiment, self-modifying actions may relieve a datacenter operator of datacenter 500 from making possibly bad configuration decisions and possibly avoiding underutilized and/or poor performing portions of a datacenter.

In at least one embodiment, datacenter 500 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 500. In at least one embodiment, trained machine learning models corresponding to one or more neural networks may be used to infer or predict information using resources described above with respect to datacenter 500 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 515 are used to perform inferencing and/or training operations associated with one or more embodiments. In at least one embodiment, inference and/or training logic 515 may be used in system FIG. 5 for inferencing or predicting operations based, at least in part, on weight parameters calculated using neural network training operations, neural network functions and/or architectures, or neural network use cases described herein.

Embodiments presented herein can provide for accurate simulation of real-world actions in a digital twin of a datacenter, and can allow for querying of the simulation using one or more fine-tuned language models.

### Computer Systems

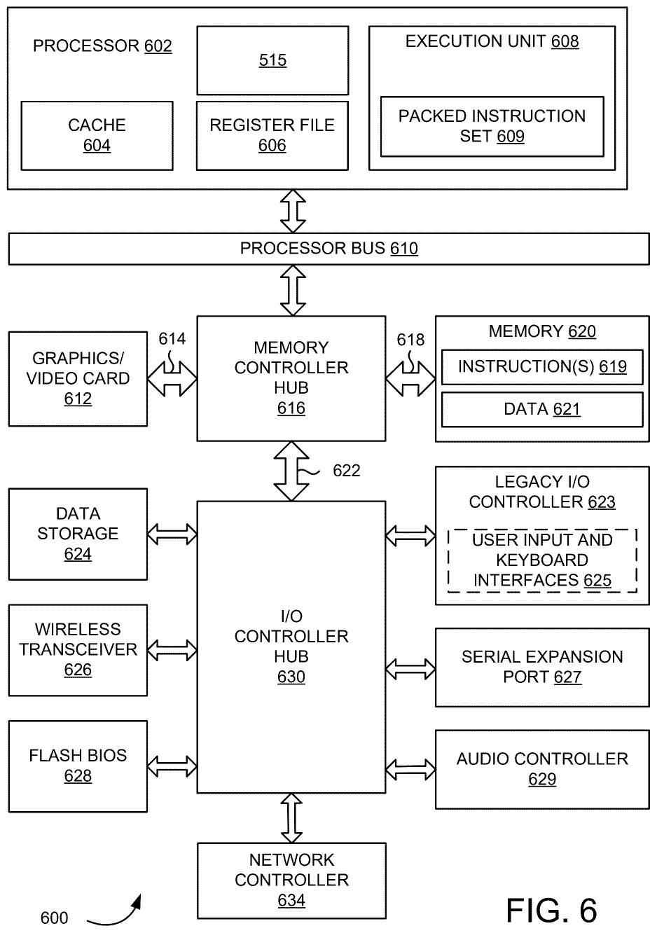

FIG. 6 is a block diagram illustrating an exemplary computer system, which may be a system with interconnected devices and components, a system-on-a-chip (SOC) or some combination thereof formed with a processor that may include execution units to execute an instruction, according to at least one embodiment. In at least one embodiment, a computer system 600 may include, without limitation, a component, such as a processor 602 to employ execution units including logic to perform algorithms for process data, in accordance with present disclosure, such as in embodiment described herein. In at least one embodiment, computer system 600 may include processors, such as PENTIUM® Processor family, Xeon™, Itanium®, Scale™ and/or StrongARM™, Intel® Core™, or Intel® Nirvana™ microprocessors available from Intel Corporation of Santa Clara, California, although other systems (including PCs having other microprocessors, engineering workstations, set-top boxes and like) may also be used. In at least one embodiment, computer system 600 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“Necks”), set-top boxes, network hubs, wide area network (“WAN”) switches, or any other system that may perform one or more instructions in accordance with at least one embodiment.

In at least one embodiment, computer system 600 may include, without limitation, processor 602 that may include, without limitation, one or more execution units 608 to perform machine learning model training and/or inferencing according to techniques described herein. In at least one embodiment, computer system 600 is a single processor desktop or server system, but in another embodiment, computer system 600 may be a multiprocessor system. In at least one embodiment, processor 602 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 602 may be coupled to a processor bus 610 that may transmit data signals between processor 602 and other components in computer system 600.

In at least one embodiment, processor 602 may include, without limitation, a Level 1 (“L1”) internal cache memory (“cache”) 604. In at least one embodiment, processor 602 may have a single internal cache or multiple levels of internal cache. In at least one embodiment, cache memory may reside external to processor 602. Other embodiments may also include a combination of both internal and external caches depending on particular implementation and needs. In at least one embodiment, a register file 606 may store different types of data in various registers including, without limitation, integer registers, floating point registers, status registers, and an instruction pointer register.

In at least one embodiment, execution unit 608, including, without limitation, logic to perform integer and floating point operations, also resides in processor 602. In at least one embodiment, processor 602 may also include a microcode (“code”) read only memory (“ROM”) that stores microcode for certain macro instructions. In at least one embodiment, execution unit 608 may include logic to handle a packed instruction set 609. In at least one embodiment, by including packed instruction set 609 in an instruction set of a general-purpose processor, along with associated circuitry to execute instructions, operations used by many multimedia applications may be performed using packed data in processor 602. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, execution unit 608 may also be used in microcontrollers, embedded processors, graphics devices, DSPs, and other types of logic circuits. In at least one embodiment, computer system 600 may include, without limitation, a memory 620. In at least one embodiment, memory 620 may be a Dynamic Random Access Memory (“DRAM”) device, a Static Random Access Memory (“SRAM”) device, a flash memory device, or another memory device. In at least one embodiment, memory 620 may store instruction(s) 619 and/or data 621 represented by data signals that may be executed by processor 602.

In at least one embodiment, a system logic chip may be coupled to processor bus 610 and memory 620. In at least one embodiment, a system logic chip may include, without limitation, a memory controller hub (“MCH”) 616, and processor 602 may communicate with MCH 616 via processor bus 610. In at least one embodiment, MCH 616 may provide a high bandwidth memory path 618 to memory 620 for instruction and data storage and for storage of graphics commands, data, and textures. In at least one embodiment, MCH 616 may direct data signals between processor 602, memory 620, and other components in computer system 600 and to bridge data signals between processor bus 610, memory 620, and a system I/O interface 622. In at least one embodiment, a system logic chip may provide a graphics port for coupling to a graphics controller. In at least one embodiment, MCH 616 may be coupled to memory 620 through high bandwidth memory path 618 and a graphics/video card 612 may be coupled to MCH 616 through an Accelerated Graphics Port (“AGP”) interconnect 614.

In at least one embodiment, computer system 600 may use system I/O interface 622 as a proprietary hub interface bus to couple MCH 616 to an I/O controller hub (“ICH”) 630. In at least one embodiment, ICH 630 may provide direct connections to some I/O devices via a local I/O bus. In at least one embodiment, a local I/O bus may include, without limitation, a high-speed I/O bus for connecting peripherals to memory 620, a chipset, and processor 602. Examples may include, without limitation, an audio controller 629, a firmware hub (“flash BIOS”) 628, a wireless transceiver 626, a data storage 624, a legacy I/O controller 623 containing user input and keyboard interfaces 625, a serial expansion port 627, such as a Universal Serial Bus (“USB”) port, and a network controller 634. In at least one embodiment, data storage 624 may comprise a hard disk drive, a floppy disk drive, a CD-ROM device, a flash memory device, or other mass storage device.

In at least one embodiment, FIG. 6 illustrates a system, which includes interconnected hardware devices or “chips”, whereas in other embodiments, FIG. 6 may illustrate an exemplary SoC In at least one embodiment, devices illustrated in FIG. 6 may be interconnected with proprietary interconnects, standardized interconnects (e.g., PCIe) or some combination thereof. In at least one embodiment, one or more components of computer system 600 are interconnected using compute express link (CXL) interconnects.

Inference and/or training logic 515 are used to perform inferencing and/or training operations associated with one or more embodiments. In at least one embodiment, inference and/or training logic 515 may be used in system FIG. 6 for inferencing or predicting operations based, at least in part, on weight parameters calculated using neural network training operations, neural network functions and/or architectures, or neural network use cases described herein.

Embodiments presented herein can provide for accurate simulation of real-world actions in a digital twin of a datacenter, and can allow for querying of the simulation using one or more fine-tuned language models.

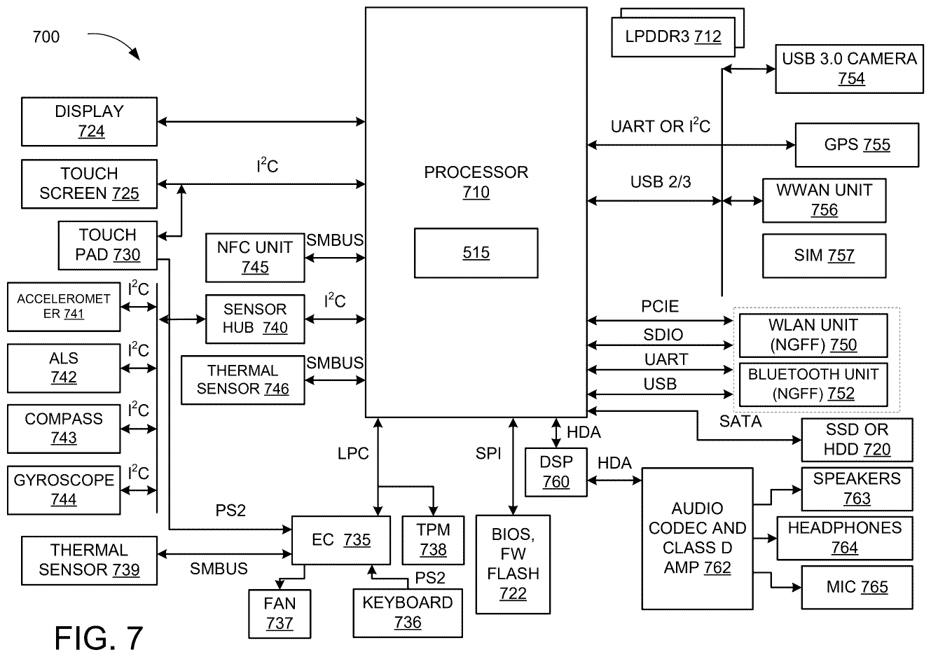

FIG. 7 is a block diagram illustrating an electronic device 700 for utilizing a processor 710, according to at least one embodiment. In at least one embodiment, electronic device 700 may be, for example and without limitation, a notebook, a tower server, a rack server, a blade server, a laptop, a desktop, a tablet, a mobile device, a phone, an embedded computer, or any other suitable electronic device.

In at least one embodiment, electronic device 700 may include, without limitation, processor 710 communicatively coupled to any suitable number or kind of components, peripherals, modules, or devices. In at least one embodiment, processor 710 is coupled using a bus or interface, such as a I²C bus, a System Management Bus (“Sambas”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3, etc.), or a Universal Asynchronous Receiver/Transmitter (“UART”) bus. In at least one embodiment, FIG. 7 illustrates a system, which includes interconnected hardware devices or “chips”, whereas in other embodiments, FIG. 7 may illustrate an exemplary SoC. In at least one embodiment, devices illustrated in FIG. 7 may be interconnected with proprietary interconnects, standardized interconnects (e.g., PCIe) or some combination thereof. In at least one embodiment, one or more components of FIG. 7 are interconnected using compute express link (CXL) interconnects.

In at least one embodiment, FIG. 7 may include a display 724, a touch screen 725, a touch pad 730, a Near Field Communications unit (“NFC”) 745, a sensor hub 740, a thermal sensor 746, an Express Chipset (“EC”) 735, a Trusted Platform Module (“TPM”) 738, BIOS/firmware/flash memory (“BIOS, FW Flash”) 722, a DSP 760, a drive 720 such as a Solid State Disk (“SSD”) or a Hard Disk Drive (“HDD”), a wireless local area network unit (“WLAN”) 750, a Bluetooth unit 752, a Wireless Wide Area Network unit (“WWAN”) 756, a Global Positioning System (GPS) unit 755, a camera (“USB 3.0 camera”) 754 such as a USB 3.0 camera, and/or a Low Power Double Data Rate (“LPDDR”) memory unit (“LPDDR3”) 715 implemented in, for example, an LPDDR3 standard. These components may each be implemented in any suitable manner.

In at least one embodiment, other components may be communicatively coupled to processor 710 through components described herein. In at least one embodiment, an accelerometer 741, an ambient light sensor (“ALS”) 742, a compass 743, and a gyroscope 744 may be communicatively coupled to sensor hub 740. In at least one embodiment, a thermal sensor 739, a fan 737, a keyboard 736, and touch pad 730 may be communicatively coupled to EC 735. In at least one embodiment, speakers 763, headphones 764, and a microphone (“mic”) 765 may be communicatively coupled to an audio unit (“audio codec and class D amp”) 762, which may in turn be communicatively coupled to DSP 760. In at least one embodiment, audio unit 762 may include, for example and without limitation, an audio coder/decoder (“codec”) and a class D amplifier. In at least one embodiment, a SIM card (“SIM”) 757 may be communicatively coupled to WWAN unit 756. In at least one embodiment, components such as WLAN unit 750 and Bluetooth unit 752, as well as WWAN unit 756 may be implemented in a Next Generation Form Factor (“NGFF”).

Inference and/or training logic 515 are used to perform inferencing and/or training operations associated with one or more embodiments. In at least one embodiment, inference and/or training logic 515 may be used in system FIG. 7 for inferencing or predicting operations based, at least in part, on weight parameters calculated using neural network training operations, neural network functions and/or architectures, or neural network use cases described herein.

Embodiments presented herein can provide for accurate simulation of real-world actions in a digital twin of a datacenter, and can allow for querying of the simulation using one or more fine-tuned language models.

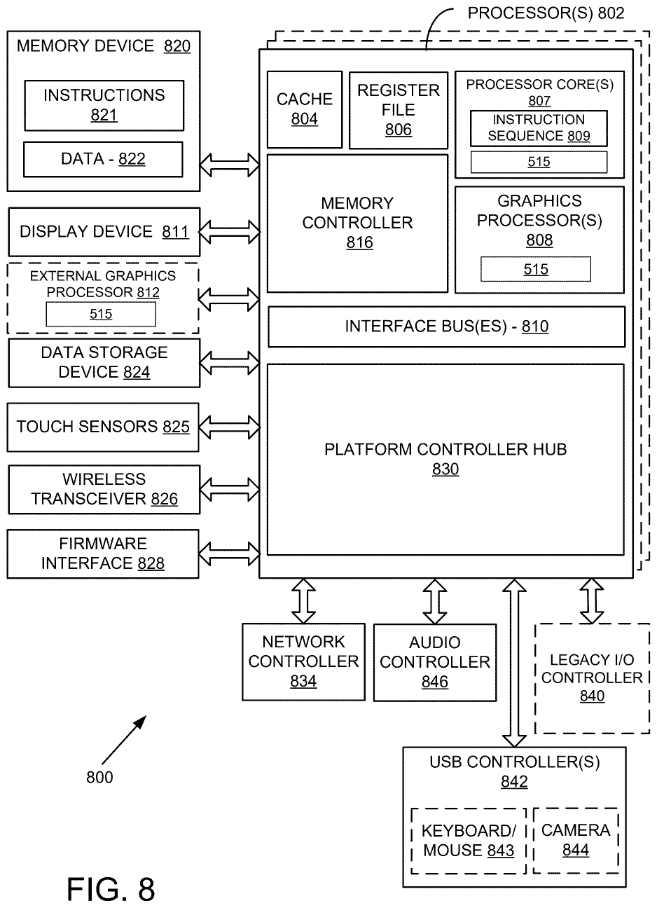

FIG. 8 is a block diagram of a processing system, according to at least one embodiment. In at least one embodiment, system 800 includes one or more processor(s) 802 and one or more graphics processor(s) 808, and may be a single processor desktop system, a multiprocessor workstation system, or a server system having a large number of processor(s) 802 or processor core(s) 807. In at least one embodiment, system 800 is a processing platform incorporated within a system-on-a-chip (SoC) integrated circuit for use in mobile, handheld, or embedded devices. In at least one embodiment, one or more graphics processor(s) 808 include one or more graphics cores.

In at least one embodiment, system 800 can include, or be incorporated within a server-based gaming platform, a game console, including a game and media console, a mobile gaming console, a handheld game console, or an online game console. In at least one embodiment, system 800 is a mobile phone, a smart phone, a tablet computing device or a mobile Internet device. In at least one embodiment, processing system 800 can also include, couple with, or be integrated within a wearable device, such as a smart watch wearable device, a smart eyewear device, an augmented reality device, or a virtual reality device. In at least one embodiment, processing system 800 is a television or set top box device having one or more processor(s) 802 and a graphical interface generated by one or more graphics processor(s) 808.

In at least one embodiment, one or more processor(s) 802 each include one or more processor core(s) 807 to process instructions which, when executed, perform operations for system and user software. In at least one embodiment, each of one or more processor core(s) 807 is configured to process a specific instruction sequence 809. In at least one embodiment, instruction sequence 809 may facilitate Complex Instruction Set Computing (CISC), Reduced Instruction Set Computing (RISC), or computing via a Very Long Instruction Word (VLIW). In at least one embodiment, processor core(s) 807 may each process a different instruction sequence 809, which may include instructions to facilitate emulation of other instruction sequences. In at least one embodiment, processor core(s) 807 may also include other processing devices, such a Digital Signal Processor (DSP).

In at least one embodiment, processor(s) 802 includes a cache memory 804. In at least one embodiment, processor(s) 802 can have a single internal cache or multiple levels of internal cache. In at least one embodiment, cache memory is shared among various components of processor(s) 802. In at least one embodiment, processor(s) 802 also uses an external cache (e.g., a Level-3 (L3) cache or Last Level Cache (LLC)) (not shown), which may be shared among processor core(s) 807 using known cache coherency techniques. In at least one embodiment, a register file 806 is additionally included in processor(s) 802, which may include different types of registers for storing different types of data (e.g., integer registers, floating point registers, status registers, and an instruction pointer register). In at least one embodiment, register file 806 may include general-purpose registers or other registers.

In at least one embodiment, one or more processor(s) 802 are coupled with one or more interface bus(es) 810 to transmit communication signals such as address, data, or control signals between processor(s) 802 and other components in system 800. In at least one embodiment, interface bus(es) 810 can be a processor bus, such as a version of a Direct Media Interface (DMI) bus. In at least one embodiment, interface bus(es) 810 is not limited to a DMI bus, and may include one or more Peripheral Component Interconnect buses (e.g., PCI, PCI Express), memory busses, or other types of interface busses. In at least one embodiment processor(s) 802 include an integrated memory controller 816 and a platform controller hub 830. In at least one embodiment, memory controller 816 facilitates communication between a memory device and other components of system 800, while platform controller hub (PCH) 830 provides connections to I/O devices via a local I/O bus.

In at least one embodiment, a memory device 820 can be a dynamic random access memory (DRAM) device, a static random access memory (SRAM) device, flash memory device, phase-change memory device, or some other memory device having suitable performance to serve as process memory. In at least one embodiment, memory device 820 can operate as system memory for system 800, to store data 822 and instructions 821 for use when one or more processor(s) 802 executes an application or process. In at least one embodiment, memory controller 816 also couples with an optional external graphics processor 812, which may communicate with one or more graphics processor(s) 808 in processor(s) 802 to perform graphics and media operations. In at least one embodiment, a display device 811 can connect to processor(s) 802. In at least one embodiment, display device 811 can include one or more of an internal display device, as in a mobile electronic device or a laptop device, or an external display device attached via a display interface (e.g., DisplayPort, etc.). In at least one embodiment, display device 811 can include a head mounted display (HMD) such as a stereoscopic display device for use in virtual reality (VR) applications or augmented reality (AR) applications.

In at least one embodiment, platform controller hub 830 enables peripherals to connect to memory device 820 and processor(s) 802 via a high-speed I/O bus. In at least one embodiment, I/O peripherals include, but are not limited to, an audio controller 846, a network controller 834, a firmware interface 828, a wireless transceiver 826, touch sensors 825, a data storage device 824 (e.g., hard disk drive, flash memory, etc.). In at least one embodiment, data storage device 824 can connect via a storage interface (e.g., SATA) or via a peripheral bus, such as a Peripheral Component Interconnect bus (e.g., PCI, PCI Express). In at least one embodiment, touch sensors 825 can include touch screen sensors, pressure sensors, or fingerprint sensors. In at least one embodiment, wireless transceiver 826 can be a Wi-Fi transceiver, a Bluetooth transceiver, or a mobile network transceiver such as a 3G, 4G, or Long Term Evolution (LTE) transceiver. In at least one embodiment, firmware interface 828 enables communication with system firmware, and can be, for example, a unified extensible firmware interface (UEFI). In at least one embodiment, network controller 834 can enable a network connection to a wired network. In at least one embodiment, a high-performance network controller (not shown) couples with interface bus(es) 810. In at least one embodiment, audio controller 846 is a multi-channel high definition audio controller. In at least one embodiment, system 800 includes an optional legacy I/O controller 840 for coupling legacy (e.g., Personal System 2 (PS/2)) devices to system 800. In at least one embodiment, platform controller hub 830 can also connect to one or more Universal Serial Bus (USB) controller(s) 842 connect input devices, such as keyboard and mouse 843 combinations, a camera 844, or other USB input devices.

In at least one embodiment, an instance of memory controller 816 and platform controller hub 830 may be integrated into a discreet external graphics processor, such as external graphics processor 812. In at least one embodiment, platform controller hub 830 and/or memory controller 816 may be external to one or more processor(s) 802. For example, in at least one embodiment, system 800 can include an external memory controller 816 and platform controller hub 830, which may be configured as a memory controller hub and peripheral controller hub within a system chipset that is in communication with processor(s) 802.

Embodiments presented herein can provide for accurate simulation of real-world actions in a digital twin of a datacenter, and can allow for querying of the simulation using one or more fine-tuned language models.

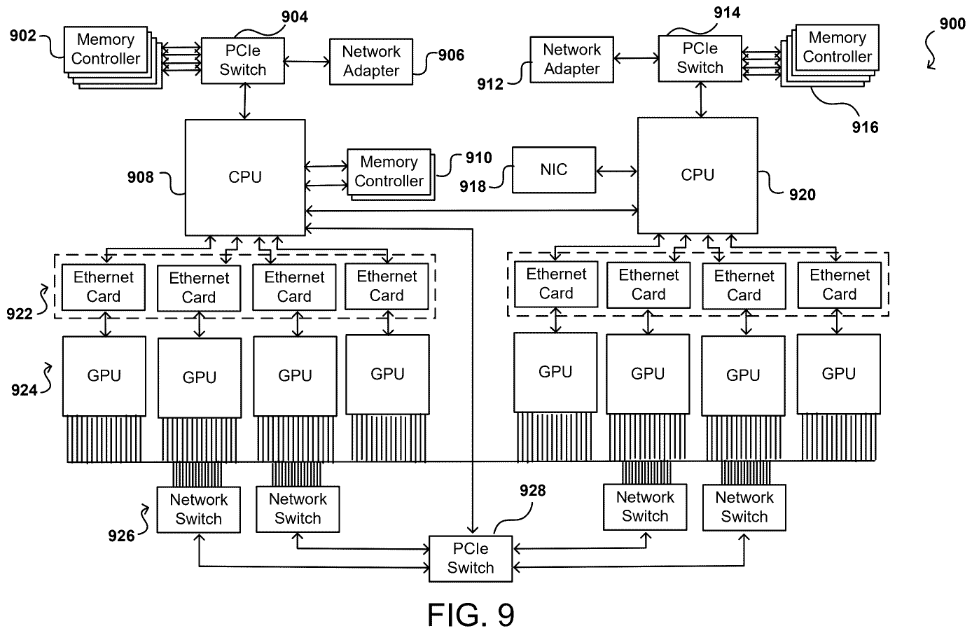

FIG. 9 illustrates an example enterprise AI system that can be used to perform at least AI-related tasks in accordance with at least one embodiment. An example of such a system is an H100 or H200 DGX system implementing the NVIDIA DGX™ platform from NVIDIA Corporation. The NVIDIA DGX™ H100/H200 Systems are built for all AI infrastructure and workloads from analytics to training to inference. The DGX H100/H200 systems are built on eight GPUs 924, such as NVIDIA H100 Tensor Core GPUs or eight NVIDIA H200 Tensor Core GPUs. Although not illustrated in FIG. 9, other types of processing units can be used as well, such as data processing units (DPUs). The illustrated system 900 includes a pair of CPUs 908, 920, such as Intel Xeon CPUs with 56 cores each. The CPUs 908, 920 are connected to the eight GPUs 924 using a set of Ethernet cards 922, such as ConnectX-7 Network Modules, which are connected in turn to a number of network switches 926, such as NVSwitches. The network switches 926 are connected to a PCIe switch 928, which can be connected back to at least one of the CPUs 908. A first CPU 908 can be connected directly to a memory controller 910, such as an NVMe controller, and to other memory controllers 902 indirectly through a PCIe switch 904, which can also connect the CPU 908 to a network adapter 906, such as a ConnectX-7 adapter. A second CPU 920 can be connected to the first CPU 908 as well as a network interface card (NIC) 918. The second CPU 920 can also be connected, through another PCIe switch 914, to a network adapter 912 and one or more memory controllers 916.

An example Nvidia DGX (Deep GPU Xceleration) implementation can include a number of servers and workstations that are geared towards enhancing deep learning applications through the use of general-purpose computing on graphics processing units (GPUs). Such systems may come in a rackmount format featuring high-performance x86 server CPUs on the motherboard. A core feature of an example DGX system is its inclusion of 8 or more NVIDIA GPU modules, which are housed on an independent system board. These GPUs can be connected either via a version of the SXM socket or a PCIe x16 slot, facilitating flexible integration within the system architecture. To manage the substantial thermal output, DGX units are equipped with heatsinks and fans designed to maintain optimal operating temperatures. This framework makes DGX units suitable for computational tasks associated with artificial intelligence and machine learning models. In one embodiment, the GPUs can be connected using an NVLink mesh network.

Embodiments presented herein can provide for accurate simulation of real-world actions in a digital twin of a datacenter, and can allow for querying of the simulation using one or more fine-tuned language models.

### Virtualized Computing Platform

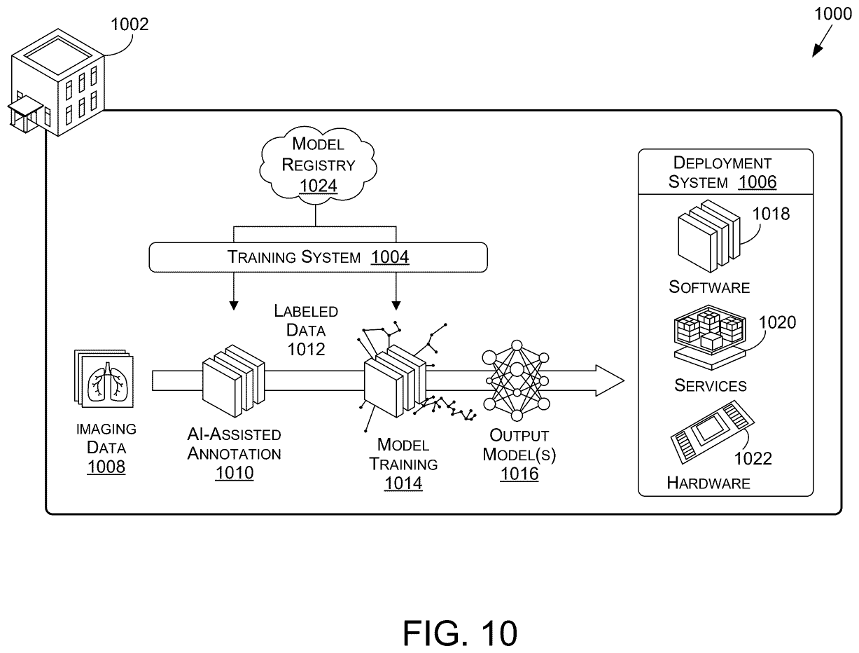

FIG. 10 is an example data flow diagram for a process 1000 of generating and deploying an image processing and inferencing pipeline, in accordance with at least one embodiment. In at least one embodiment, process 1000 may be deployed for use with imaging devices, processing devices, and/or other device types at one or more facilities 1002. Process 1000 may be executed within a training system 1004 and/or a deployment system 1006. In at least one embodiment, training system 1004 may be used to perform training, deployment, and implementation of machine learning models (e.g., neural networks, object detection algorithms, computer vision algorithms, etc.) for use in deployment system 1006. In at least one embodiment, deployment system 1006 may be configured to offload processing and compute resources among a distributed computing environment to reduce infrastructure requirements at facility 1002. In at least one embodiment, one or more applications in a pipeline may use or call upon services (e.g., inference, visualization, compute, AI, etc.) of deployment system 1006 during execution of applications.

In at least one embodiment, some of applications used in advanced processing and inferencing pipelines may use machine learning models or other AI to perform one or more processing steps. In at least one embodiment, machine learning models may be trained at facility 1002 using data 1008 (such as imaging data) generated at facility 1002 (and stored on one or more picture archiving and communication system (PACS) servers at facility 1002), may be trained using imaging or sequencing data 1008 from another facility(ies), or a combination thereof. In at least one embodiment, training system 1004 may be used to provide applications, services, and/or other resources for generating working, deployable machine learning models for deployment system 1006.

In at least one embodiment, model registry 1024 may be backed by object storage that may support versioning and object metadata. In at least one embodiment, object storage may be accessible through, for example, a cloud storage compatible application programming interface (API) from within a cloud platform. In at least one embodiment, machine learning models within model registry 1024 may uploaded, listed, modified, or deleted by developers or partners of a system interacting with an API. In at least one embodiment, an API may provide access to methods that allow users with appropriate credentials to associate models with applications, such that models may be executed as part of execution of containerized instantiations of applications.

In at least one embodiment, training system 1004 may include a scenario where facility 1002 is training their own machine learning model, or has an existing machine learning model that needs to be optimized or updated. In at least one embodiment, imaging data 1008 generated by imaging device(s), sequencing devices, and/or other device types may be received. In at least one embodiment, once imaging data 1008 is received, AI-assisted annotation 1010 may be used to aid in generating annotations corresponding to imaging data 1008 to be used as ground truth data for a machine learning model. In at least one embodiment, AI-assisted annotation 1010 may include one or more machine learning models (e.g., convolutional neural networks (CNNs)) that may be trained to generate annotations corresponding to certain types of imaging data 1008 (e.g., from certain devices). In at least one embodiment, AI-assisted annotation 1010 may then be used directly, or may be adjusted or fine-tuned using an annotation tool to generate ground truth data. In at least one embodiment, AI-assisted annotation 1010, labeled data 1012, or a combination thereof may be used as ground truth data for training a machine learning model. In at least one embodiment, a trained machine learning model may be referred to as output model(s) 1016, and may be used by deployment system 1006, as described herein.

In at least one embodiment, a training pipeline may include a scenario where facility 1002 needs a machine learning model for use in performing one or more processing tasks for one or more applications in deployment system 1006, but facility 1002 may not currently have such a machine learning model (or may not have a model that is optimized, efficient, or effective for such purposes). In at least one embodiment, an existing machine learning model may be selected from a model registry 1024. In at least one embodiment, model registry 1024 may include machine learning models trained to perform a variety of different inference tasks on imaging data. In at least one embodiment, machine learning models in model registry 1024 may have been trained on imaging data from different facilities than facility 1002 (e.g., facilities remotely located). In at least one embodiment, machine learning models may have been trained on imaging data from one location, two locations, or any number of locations. In at least one embodiment, when being trained on imaging data from a specific location, training may take place at that location, or at least in a manner that protects confidentiality of imaging data or restricts imaging data from being transferred off-premises. In at least one embodiment, once a model is trained—or partially trained—at one location, a machine learning model may be added to model registry 1024. In at least one embodiment, a machine learning model may then be retrained, or updated, at any number of other facilities, and a retrained or updated model may be made available in model registry 1024. In at least one embodiment, a machine learning model may then be selected from model registry 1024—and referred to as output model(s) 1016—and may be used in deployment system 1006 to perform one or more processing tasks for one or more applications of a deployment system.

In at least one embodiment, a scenario may include facility 1002 requiring a machine learning model for use in performing one or more processing tasks for one or more applications in deployment system 1006, but facility 1002 may not currently have such a machine learning model (or may not have a model that is optimized, efficient, or effective for such purposes). In at least one embodiment, a machine learning model selected from model registry 1024 may not be fine-tuned or optimized for imaging data 1008 generated at facility 1002 because of differences in populations, robustness of training data used to train a machine learning model, diversity in anomalies of training data, and/or other issues with training data. In at least one embodiment, AI-assisted annotation 1010 may be used to aid in generating annotations corresponding to imaging data 1008 to be used as ground truth data for retraining or updating a machine learning model. In at least one embodiment, labeled data 1012 may be used as ground truth data for training a machine learning model. In at least one embodiment, retraining or updating a machine learning model may be referred to as model training 1014. In at least one embodiment, model training 1014—e.g., AI-assisted annotation 1010, labeled data 1012, or a combination thereof—may be used as ground truth data for retraining or updating a machine learning model. In at least one embodiment, a trained machine learning model may be referred to as output model(s) 1016, and may be used by deployment system 1006, as described herein.

In at least one embodiment, deployment system 1006 may include software 1018, services 1020, hardware 1022, and/or other components, features, and functionality. In at least one embodiment, deployment system 1006 may include a software “stack,” such that software 1018 may be built on top of services 1020 and may use services 1020 to perform some or all of processing tasks, and services 1020 and software 1018 may be built on top of hardware 1022 and use hardware 1022 to execute processing, storage, and/or other compute tasks of deployment system 1006. In at least one embodiment, software 1018 may include any number of different containers, where each container may execute an instantiation of an application. In at least one embodiment, each application may perform one or more processing tasks in an advanced processing and inferencing pipeline (e.g., inferencing, object detection, feature detection, segmentation, image enhancement, calibration, etc.). In at least one embodiment, an advanced processing and inferencing pipeline may be defined based on selections of different containers that are desired or required for processing imaging data 1008, in addition to containers that receive and configure imaging data for use by each container and/or for use by facility 1002 after processing through a pipeline (e.g., to convert outputs back to a usable data type). In at least one embodiment, a combination of containers within software 1018 (e.g., that make up a pipeline) may be referred to as a virtual instrument (as described in more detail herein), and a virtual instrument may leverage services 1020 and hardware 1022 to execute some or all processing tasks of applications instantiated in containers.

In at least one embodiment, a data processing pipeline may receive input data (e.g., imaging data 1008) in a specific format in response to an inference request (e.g., a request from a user of deployment system 1006). In at least one embodiment, input data may be representative of one or more images, video, and/or other data representations generated by one or more imaging devices. In at least one embodiment, data may undergo pre-processing as part of data processing pipeline to prepare data for processing by one or more applications. In at least one embodiment, post-processing may be performed on an output of one or more inferencing tasks or other processing tasks of a pipeline to prepare an output data for a next application and/or to prepare output data for transmission and/or use by a user (e.g., as a response to an inference request). In at least one embodiment, inferencing tasks may be performed by one or more machine learning models, such as trained or deployed neural networks, which may include output model(s) 1016 of training system 1004.

In at least one embodiment, tasks of data processing pipeline may be encapsulated in a container(s) that each represents a discrete, fully functional instantiation of an application and virtualized computing environment that is able to reference machine learning models. In at least one embodiment, containers or applications may be published into a private (e.g., limited access) area of a container registry (described in more detail herein), and trained or deployed models may be stored in model registry 1024 and associated with one or more applications. In at least one embodiment, images of applications (e.g., container images) may be available in a container registry, and once selected by a user from a container registry for deployment in a pipeline, an image may be used to generate a container for an instantiation of an application for use by a user's system.

In at least one embodiment, developers (e.g., software developers, clinicians, doctors, etc.) may develop, publish, and store applications (e.g., as containers) for performing image processing and/or inferencing on supplied data. In at least one embodiment, development, publishing, and/or storing may be performed using a software development kit (SDK) associated with a system (e.g., to ensure that an application and/or container developed is compliant with or compatible with a system). In at least one embodiment, an application that is developed may be tested locally (e.g., at a first facility, on data from a first facility) with an SDK which may support at least some of services 1020 as a system. In at least one embodiment, because DICOM objects may contain anywhere from one to hundreds of images or other data types, and due to a variation in data, a developer may be responsible for managing (e.g., setting constructs for, building pre-processing into an application, etc.) extraction and preparation of incoming data. In at least one embodiment, once validated by process 1000 (e.g., for accuracy), an application may be available in a container registry for selection and/or implementation by a user to perform one or more processing tasks with respect to data at a facility (e.g., a second facility) of a user.

In at least one embodiment, developers may then share applications or containers through a network for access and use by users of a system. In at least one embodiment, completed and validated applications or containers may be stored in a container registry and associated machine learning models may be stored in model registry 1024. In at least one embodiment, a requesting entity—who provides an inference or image processing request—may browse a container registry and/or model registry 1024 for an application, container, dataset, machine learning model, etc., select a desired combination of elements for inclusion in data processing pipeline, and submit an imaging processing request. In at least one embodiment, a request may include input data (and associated patient data, in some examples) that is necessary to perform a request, and/or may include a selection of application(s) and/or machine learning models to be executed in processing a request. In at least one embodiment, a request may then be passed to one or more components of deployment system 1006 (e.g., a cloud) to perform processing of data processing pipeline. In at least one embodiment, processing by deployment system 1006 may include referencing selected elements (e.g., applications, containers, models, etc.) from a container registry and/or model registry 1024. In at least one embodiment, once results are generated by a pipeline, results may be returned to a user for reference (e.g., for viewing in a viewing application suite executing on a local, on-premises workstation or terminal).

In at least one embodiment, to aid in processing or execution of applications or containers in pipelines, services 1020 may be leveraged. In at least one embodiment, services 1020 may include compute services, artificial intelligence (AI) services, visualization services, and/or other service types. In at least one embodiment, services 1020 may provide functionality that is common to one or more applications in software 1018, so functionality may be abstracted to a service that may be called upon or leveraged by applications. In at least one embodiment, functionality provided by services 1020 may run dynamically and more efficiently, while also scaling well by allowing applications to process data in parallel (e.g., using a parallel computing platform). In at least one embodiment, rather than each application that shares a same functionality offered by services 1020 being required to have a respective instance of services 1020, services 1020 may be shared between and among various applications. In at least one embodiment, services may include an inference server or engine that may be used for executing detection or segmentation tasks, as non-limiting examples. In at least one embodiment, a model training service may be included that may provide machine learning model training and/or retraining capabilities. In at least one embodiment, a data augmentation service may further be included that may provide GPU accelerated data (e.g., DICOM, RIS, CIS, REST compliant, RPC, raw, etc.) extraction, resizing, scaling, and/or other augmentation. In at least one embodiment, a visualization service may be used that may add image rendering effects-such as ray-tracing, rasterization, denoising, sharpening, etc.-to add realism to two-dimensional (2D) and/or three-dimensional (3D) models. In at least one embodiment, virtual instrument services may be included that provide for beam-forming, segmentation, inferencing, imaging, and/or support for other applications within pipelines of virtual instruments.

In at least one embodiment, where services 1020 includes an AI service (e.g., an inference service), one or more machine learning models may be executed by calling upon (e.g., as an API call) an inference service (e.g., an inference server) to execute machine learning model(s), or processing thereof, as part of application execution. In at least one embodiment, where another application includes one or more machine learning models for segmentation tasks, an application may call upon an inference service to execute machine learning models for performing one or more of processing operations associated with segmentation tasks. In at least one embodiment, software 1018 implementing advanced processing and inferencing pipeline that includes segmentation application and anomaly detection application may be streamlined because each application may call upon a same inference service to perform one or more inferencing tasks.

In at least one embodiment, hardware 1022 may include GPUs, CPUs, graphics cards, an AI/deep learning system (e.g., an AI supercomputer, such as NVIDIA's DGX), a cloud platform, or a combination thereof. In at least one embodiment, different types of hardware 1022 may be used to provide efficient, purpose-built support for software 1018 and services 1020 in deployment system 1006. In at least one embodiment, use of GPU processing may be implemented for processing locally (e.g., at facility 1002), within an AI/deep learning system, in a cloud system, and/or in other processing components of deployment system 1006 to improve efficiency, accuracy, and efficacy of image processing and generation. In at least one embodiment, software 1018 and/or services 1020 may be optimized for GPU processing with respect to deep learning, machine learning, and/or high-performance computing, as non-limiting examples. In at least one embodiment, at least some of computing environment of deployment system 1006 and/or training system 1004 may be executed in a datacenter one or more supercomputers or high performance computing systems, with GPU optimized software (e.g., hardware and software combination of NVIDIA's DGX System). In at least one embodiment, hardware 1022 may include any number of GPUs that may be called upon to perform processing of data in parallel, as described herein. In at least one embodiment, cloud platform may further include GPU processing for GPU-optimized execution of deep learning tasks, machine learning tasks, or other computing tasks. In at least one embodiment, cloud platform (e.g., NVIDIA's NGC) may be executed using an AI/deep learning supercomputer(s) and/or GPU-optimized software (e.g., as provided on NVIDIA's DGX Systems) as a hardware abstraction and scaling platform. In at least one embodiment, cloud platform may integrate an application container clustering system or orchestration system (e.g., KUBERNETES) on multiple GPUs to enable seamless scaling and load balancing.

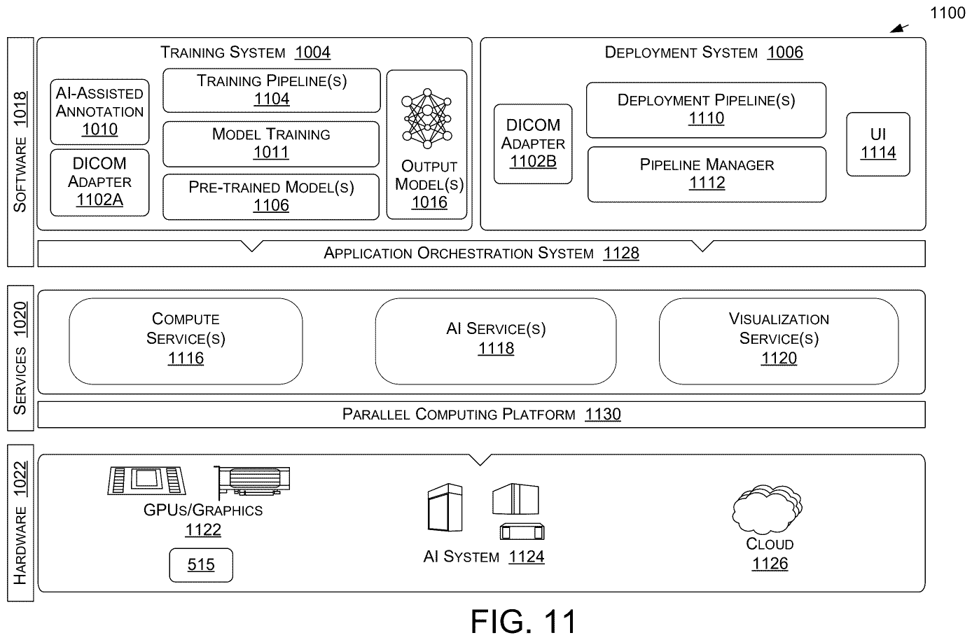

FIG. 11 is a system diagram for an example system 1100 for generating and deploying an imaging deployment pipeline, in accordance with at least one embodiment. In at least one embodiment, system 1100 may be used to implement processes including advanced processing and inferencing pipelines. In at least one embodiment, system 1100 may include training system 1004 and deployment system 1006. In at least one embodiment, training system 1004 and deployment system 1006 may be implemented using software 1018, services 1020, and/or hardware 1022, as described herein.

In at least one embodiment, system 1100 (e.g., training system 1004 and/or deployment system 1006) may implemented in a cloud computing environment (e.g., using cloud 1126). In at least one embodiment, system 1100 may be implemented locally with respect to a healthcare services facility, or as a combination of both cloud and local computing resources. In at least one embodiment, access to APIs in cloud 1126 may be restricted to authorized users through enacted security measures or protocols. In at least one embodiment, a security protocol may include web tokens that may be signed by an authentication (e.g., AuthN, AuthZ, Gluecon, etc.) service and may carry appropriate authorization. In at least one embodiment, APIs of virtual instruments (described herein), or other instantiations of system 1100, may be restricted to a set of public IPs that have been vetted or authorized for interaction.

In at least one embodiment, various components of system 1100 may communicate between and among one another using any of a variety of different network types, including but not limited to local area networks (LANs) and/or wide area networks (WANs) via wired and/or wireless communication protocols. In at least one embodiment, communication between facilities and components of system 1100 (e.g., for transmitting inference requests, for receiving results of inference requests, etc.) may be communicated over data bus(ses), wireless data protocols (Wi-Fi), wired data protocols (e.g., Ethernet), etc.

In at least one embodiment, training system 1004 may execute training pipelines 1104, similar to those described herein with respect to FIG. 10. In at least one embodiment, where one or more machine learning models are to be used in deployment pipeline(s) 1110 by deployment system 1006, training pipelines 1104 may be used to train or retrain one or more (e.g. pre-trained) models, and/or implement one or more of pre-trained models 1106 (e.g., without a need for retraining or updating). In at least one embodiment, as a result of training pipelines 1104, output model(s) 1016 may be generated. In at least one embodiment, training pipelines 1104 may include any number of processing steps, such as but not limited to imaging data (or other input data) conversion or adaption In at least one embodiment, for different machine learning models used by deployment system 1006, different training pipelines 1104 may be used. In at least one embodiment, training pipeline 1104 similar to a first example described with respect to FIG. 10 may be used for a first machine learning model, training pipeline 1104 similar to a second example described with respect to FIG. 10 may be used for a second machine learning model, and training pipeline 1104 similar to a third example described with respect to FIG. 10 may be used for a third machine learning model. In at least one embodiment, any combination of tasks within training system 1004 may be used depending on what is required for each respective machine learning model. In at least one embodiment, one or more of machine learning models may already be trained and ready for deployment so machine learning models may not undergo any processing by training system 1004, and may be implemented by deployment system 1006.

In at least one embodiment, output model(s) 1016 and/or pre-trained models 1106 may include any types of machine learning models depending on implementation or embodiment. In at least one embodiment, and without limitation, machine learning models used by system 1100 may include machine learning model(s) using linear regression, logistic regression, decision trees, support vector machines (SVM), Naïve Bayes, k-nearest neighbor (Knn), K means clustering, random forest, dimensionality reduction algorithms, gradient boosting algorithms, neural networks (e.g., auto-encoders, convolutional, recurrent, perceptrons, Long/Short Term Memory (LSTM), Hopfield, Boltzmann, deep belief, deconvolutional, generative adversarial, liquid state machine, etc.), and/or other types of machine learning models.

In at least one embodiment, training pipelines 1104 may include AI-assisted annotation, as described in more detail herein with respect to at least FIG. 11. In at least one embodiment, labeled data 1012 (e.g., traditional annotation) may be generated by any number of techniques. In at least one embodiment, labels or other annotations may be generated within a drawing program (e.g., an annotation program), a computer aided design (CAD) program, a labeling program, another type of program suitable for generating annotations or labels for ground truth, and/or may be hand drawn, in some examples. In at least one embodiment, ground truth data may be synthetically produced (e.g., generated from computer models or renderings), real produced (e.g., designed and produced from real-world data), machine-automated (e.g., using feature analysis and learning to extract features from data and then generate labels), human annotated (e.g., labeler, or annotation expert, defines location of labels), and/or a combination thereof. In at least one embodiment, for each instance of imaging data 1008 (or other data type used by machine learning models), there may be corresponding ground truth data generated by training system 1004. In at least one embodiment, AI-assisted annotation may be performed as part of deployment pipeline(s) 1110; either in addition to, or in lieu of AI-assisted annotation included in training pipelines 1104. In at least one embodiment, system 1100 may include a multi-layer platform that may include a software layer (e.g., software 1018) of diagnostic applications (or other application types) that may perform one or more medical imaging and diagnostic functions. In at least one embodiment, system 1100 may be communicatively coupled to (e.g., via encrypted links) PACS server networks of one or more facilities. In at least one embodiment, system 1100 may be configured to access and referenced data from PACS servers to perform operations, such as training machine learning models, deploying machine learning models, image processing, inferencing, and/or other operations.

In at least one embodiment, a software layer may be implemented as a secure, encrypted, and/or authenticated API through which applications or containers may be invoked (e.g., called) from an external environment(s) (e.g., facility 1002). In at least one embodiment, applications may then call or execute one or more services 1020 for performing compute, AI, or visualization tasks associated with respective applications, and software 1018 and/or services 1020 may leverage hardware 1022 to perform processing tasks in an effective and efficient manner. In at least one embodiment, communications sent to, or received by, a training system 1004 and a deployment system 1006 may occur using a pair of DICOM adapters 1102A, 1102B.

In at least one embodiment, deployment system 1006 may execute deployment pipeline(s) 1110. In at least one embodiment, deployment pipeline(s) 1110 may include any number of applications that may be sequentially, non-sequentially, or otherwise applied to imaging data (and/or other data types) generated by imaging devices, sequencing devices, genomics devices, etc.—including AI-assisted annotation, as described above. In at least one embodiment, as described herein, a deployment pipeline(s) 1110 for an individual device may be referred to as a virtual instrument for a device (e.g., a virtual ultrasound instrument, a virtual CT scan instrument, a virtual sequencing instrument, etc.). In at least one embodiment, for a single device, there may be more than one deployment pipeline(s) 1110 depending on information desired from data generated by a device. In at least one embodiment, where detections of anomalies are desired from an MRI machine, there may be a first deployment pipeline(s) 1110, and where image enhancement is desired from output of an MRI machine, there may be a second deployment pipeline(s) 1110.

In at least one embodiment, an image generation application may include a processing task that includes use of a machine learning model. In at least one embodiment, a user may desire to use their own machine learning model, or to select a machine learning model from model registry 1024. In at least one embodiment, a user may implement their own machine learning model or select a machine learning model for inclusion in an application for performing a processing task. In at least one embodiment, applications may be selectable and customizable, and by defining constructs of applications, deployment and implementation of applications for a particular user are presented as a more seamless user experience. In at least one embodiment, by leveraging other features of system 1100—such as services 1020 and hardware 1022—deployment pipeline(s) 1110 may be even more user friendly, provide for easier integration, and produce more accurate, efficient, and timely results.

In at least one embodiment, deployment system 1006 may include a user interface (“UI”) 1114 (e.g., a graphical user interface, a web interface, etc.) that may be used to select applications for inclusion in deployment pipeline(s) 1110, arrange applications, modify or change applications or parameters or constructs thereof, use and interact with deployment pipeline(s) 1110 during set-up and/or deployment, and/or to otherwise interact with deployment system 1006. In at least one embodiment, although not illustrated with respect to training system 1004, UI 1114 (or a different user interface) may be used for selecting models for use in deployment system 1006, for selecting models for training, or retraining, in training system 1004, and/or for otherwise interacting with training system 1004.

In at least one embodiment, pipeline manager 1112 may be used, in addition to an application orchestration system 1128, to manage interaction between applications or containers of deployment pipeline(s) 1110 and services 1020 and/or hardware 1022. In at least one embodiment, pipeline manager 1112 may be configured to facilitate interactions from application to application, from application to services 1020, and/or from application or service to hardware 1022. In at least one embodiment, although illustrated as included in software 1018, this is not intended to be limiting, and in some examples pipeline manager 1112 may be included in services 1020. In at least one embodiment, application orchestration system 1128 (e.g., Kubernetes, DOCKER, etc.) may include a container orchestration system that may group applications into containers as logical units for coordination, management, scaling, and deployment. In at least one embodiment, by associating applications from deployment pipeline(s) 1110 (e.g., a reconstruction application, a segmentation application, etc.) with individual containers, each application may execute in a self-contained environment (e.g., at a kernel level) to increase speed and efficiency.

In at least one embodiment, each application and/or container (or image thereof) may be individually developed, modified, and deployed (e.g., a first user or developer may develop, modify, and deploy a first application and a second user or developer may develop, modify, and deploy a second application separate from a first user or developer), which may allow for focus on, and attention to, a task of a single application and/or container(s) without being hindered by tasks of another application(s) or container(s). In at least one embodiment, communication, and cooperation between different containers or applications may be aided by pipeline manager 1112 and application orchestration system 1128. In at least one embodiment, so long as an expected input and/or output of each container or application is known by a system (e.g., based on constructs of applications or containers), application orchestration system 1128 and/or pipeline manager 1112 may facilitate communication among and between, and sharing of resources among and between, each of applications or containers. In at least one embodiment, because one or more of applications or containers in deployment pipeline(s) 1110 may share same services and resources, application orchestration system 1128 may orchestrate, load balance, and determine sharing of services or resources between and among various applications or containers. In at least one embodiment, a scheduler may be used to track resource requirements of applications or containers, current usage or planned usage of these resources, and resource availability. In at least one embodiment, a scheduler may thus allocate resources to different applications and distribute resources between and among applications in view of requirements and availability of a system. In some examples, a scheduler (and/or other component of application orchestration system 1128) may determine resource availability and distribution based on constraints imposed on a system (e.g., user constraints), such as quality of service (QoS), urgency of need for data outputs (e.g., to determine whether to execute real-time processing or delayed processing), etc.

In at least one embodiment, services 1020 leveraged by and shared by applications or containers in deployment system 1006 may include compute service(s) 1116, AI service(s) 1118, visualization service(s) 1120, and/or other service types. In at least one embodiment, applications may call (e.g., execute) one or more of services 1020 to perform processing operations for an application. In at least one embodiment, compute service(s) 1116 may be leveraged by applications to perform super-computing or other high-performance computing (HPC) tasks. In at least one embodiment, compute service(s) 1116 may be leveraged to perform parallel processing (e.g., using a parallel computing platform 1130) for processing data through one or more of applications and/or one or more tasks of a single application, substantially simultaneously. In at least one embodiment, parallel computing platform 1130 (e.g., NVIDIA's CUDA) may enable general purpose computing on GPUs (GPGPU) (e.g., GPUs/Graphics 1122). In at least one embodiment, a software layer of parallel computing platform 1130 may provide access to virtual instruction sets and parallel computational elements of GPUs, for execution of compute kernels. In at least one embodiment, parallel computing platform 1130 may include memory and, in some embodiments, a memory may be shared between and among multiple containers, and/or between and among different processing tasks within a single container. In at least one embodiment, inter-process communication (IPC) calls may be generated for multiple containers and/or for multiple processes within a container to use same data from a shared segment of memory of parallel computing platform 1130 (e.g., where multiple different stages of an application or multiple applications are processing same information). In at least one embodiment, rather than making a copy of data and moving data to different locations in memory (e.g., a read/write operation), same data in same location of a memory may be used for any number of processing tasks (e.g., at a same time, at different times, etc.). In at least one embodiment, as data is used to generate new data as a result of processing, this information of a new location of data may be stored and shared between various applications. In at least one embodiment, location of data and a location of updated or modified data may be part of a definition of how a payload is understood within containers.

In at least one embodiment, AI service(s) 1118 may be leveraged to perform inferencing services for executing machine learning model(s) associated with applications (e.g., tasked with performing one or more processing tasks of an application). In at least one embodiment, AI service(s) 1118 may leverage AI system 1124 to execute machine learning model(s) (e.g., neural networks, such as CNNs) for segmentation, reconstruction, object detection, feature detection, classification, and/or other inferencing tasks. In at least one embodiment, applications of deployment pipeline(s) 1110 may use one or more of output model(s) 1016 from training system 1004 and/or other models of applications to perform inference on imaging data. In at least one embodiment, two or more examples of inferencing using application orchestration system 1128 (e.g., a scheduler) may be available. In at least one embodiment, a first category may include a high priority/low latency path that may achieve higher service level agreements, such as for performing inference on urgent requests during an emergency, or for a radiologist during diagnosis. In at least one embodiment, a second category may include a standard priority path that may be used for requests that may be non-urgent or where analysis may be performed at a later time. In at least one embodiment, application orchestration system 1128 may distribute resources (e.g., services 1020 and/or hardware 1022) based on priority paths for different inferencing tasks of AI service(s) 1118.

In at least one embodiment, shared storage may be mounted to AI service(s) 1118 within system 1100. In at least one embodiment, shared storage may operate as a cache (or other storage device type) and may be used to process inference requests from applications. In at least one embodiment, when an inference request is submitted, a request may be received by a set of API instances of deployment system 1006, and one or more instances may be selected (e.g., for best fit, for load balancing, etc.) to process a request. In at least one embodiment, to process a request, a request may be entered into a database, a machine learning model may be located from model registry 1024 if not already in a cache, a validation step may ensure appropriate machine learning model is loaded into a cache (e.g., shared storage), and/or a copy of a model may be saved to a cache. In at least one embodiment, a scheduler (e.g., of pipeline manager 1112) may be used to launch an application that is referenced in a request if an application is not already running or if there are not enough instances of an application. In at least one embodiment, if an inference server is not already launched to execute a model, an inference server may be launched. Any number of inference servers may be launched per model. In at least one embodiment, in a pull model, in which inference servers are clustered, models may be cached whenever load balancing is advantageous. In at least one embodiment, inference servers may be statically loaded in corresponding, distributed servers.

In at least one embodiment, inferencing may be performed using an inference server that runs in a container. In at least one embodiment, an instance of an inference server may be associated with a model (and optionally a plurality of versions of a model). In at least one embodiment, if an instance of an inference server does not exist when a request to perform inference on a model is received, a new instance may be loaded. In at least one embodiment, when starting an inference server, a model may be passed to an inference server such that a same container may be used to serve different models so long as inference server is running as a different instance.

In at least one embodiment, during application execution, an inference request for a given application may be received, and a container (e.g., hosting an instance of an inference server) may be loaded (if not already), and a start procedure may be called. In at least one embodiment, pre-processing logic in a container may load, decode, and/or perform any additional pre-processing on incoming data (e.g., using a CPU(s) and/or GPU(s)). In at least one embodiment, once data is prepared for inference, a container may perform inference as necessary on data. In at least one embodiment, this may include a single inference call on one image (e.g., a hand X-ray), or may require inference on hundreds of images (e.g., a chest CT). In at least one embodiment, an application may summarize results before completing, which may include, without limitation, a single confidence score, pixel level-segmentation, voxel-level segmentation, generating a visualization, or generating text to summarize findings. In at least one embodiment, different models or applications may be assigned different priorities. For example, some models may have a real-time (TAT<1 min) priority while others may have lower priority (e.g., TAT<10 min). In at least one embodiment, model execution times may be measured from requesting institution or entity and may include partner network traversal time, as well as execution on an inference service.

In at least one embodiment, transfer of requests between services 1020 and inference applications may be hidden behind a software development kit (SDK), and robust transport may be provide through a queue. In at least one embodiment, a request will be placed in a queue via an API for an individual application/tenant ID combination and an SDK will pull a request from a queue and give a request to an application. In at least one embodiment, a name of a queue may be provided in an environment from where an SDK will pick it up. In at least one embodiment, asynchronous communication through a queue may be useful as it may allow any instance of an application to pick up work as it becomes available. Results may be transferred back through a queue, to ensure no data is lost. In at least one embodiment, queues may also provide an ability to segment work, as highest priority work may go to a queue with most instances of an application connected to it, while lowest priority work may go to a queue with a single instance connected to it that processes tasks in an order received. In at least one embodiment, an application may run on a GPU-accelerated instance generated in cloud 1126, and an inference service may perform inferencing on a GPU.

In at least one embodiment, visualization service(s) 1120 may be leveraged to generate visualizations for viewing outputs of applications and/or deployment pipeline(s) 1110. In at least one embodiment, GPUs/Graphics 1122 may be leveraged by visualization service(s) 1120 to generate visualizations. In at least one embodiment, rendering effects, such as ray-tracing, may be implemented by visualization service(s) 1120 to generate higher quality visualizations. In at least one embodiment, visualizations may include, without limitation, 2D image renderings, 3D volume renderings, 3D volume reconstruction, 2D tomographic slices, virtual reality displays, augmented reality displays, etc. In at least one embodiment, virtualized environments may be used to generate a virtual interactive display or environment (e.g., a virtual environment) for interaction by users of a system (e.g., doctors, nurses, radiologists, etc.). In at least one embodiment, visualization service(s) 1120 may include an internal visualizer, cinematics, and/or other rendering or image processing capabilities or functionality (e.g., ray tracing, rasterization, internal optics, etc.).

In at least one embodiment, hardware 1022 may include GPUs/Graphics 1122, AI system 1124, cloud 1126, and/or any other hardware used for executing training system 1004 and/or deployment system 1006. In at least one embodiment, GPUs/Graphics 1122 (e.g., NVIDIA's TESLA and/or QUADRO GPUs) may include any number of GPUs that may be used for executing processing tasks of compute service(s) 1116, AI service(s) 1118, visualization service(s) 1120, other services, and/or any of features or functionality of software 1018. For example, with respect to AI service(s) 1118, GPUs/Graphics 1122 may be used to perform pre-processing on imaging data (or other data types used by machine learning models), post-processing on outputs of machine learning models, and/or to perform inferencing (e.g., to execute machine learning models). In at least one embodiment, cloud 1126, AI system 1124, and/or other components of system 1100 may use GPUs/Graphics 1122. In at least one embodiment, cloud 1126 may include a GPU-optimized platform for deep learning tasks. In at least one embodiment, AI system 1124 may use GPUs, and cloud 1126—or at least a portion tasked with deep learning or inferencing—may be executed using one or more AI systems 1124. As such, although hardware 1022 is illustrated as discrete components, this is not intended to be limiting, and any components of hardware 1022 may be combined with, or leveraged by, any other components of hardware 1022.

In at least one embodiment, AI system 1124 may include a purpose-built computing system (e.g., a super-computer or an HPC) configured for inferencing, deep learning, machine learning, and/or other artificial intelligence tasks. In at least one embodiment, AI system 1124 (e.g., NVIDIA's DGX) may include GPU-optimized software (e.g., a software stack) that may be executed using a plurality of GPUs/Graphics 1122, in addition to CPUs, RAM, storage, and/or other components, features, or functionality. In at least one embodiment, one or more AI systems 1124 may be implemented in cloud 1126 (e.g., in a datacenter) for performing some or all of AI-based processing tasks of system 1100.

In at least one embodiment, cloud 1126 may include a GPU-accelerated infrastructure (e.g., NVIDIA's NGC) that may provide a GPU-optimized platform for executing processing tasks of system 1100. In at least one embodiment, cloud 1126 may include an AI system 1124 for performing one or more of AI-based tasks of system 1100 (e.g., as a hardware abstraction and scaling platform). In at least one embodiment, cloud 1126 may integrate with application orchestration system 1128 leveraging multiple GPUs to enable seamless scaling and load balancing between and among applications and services 1020. In at least one embodiment, cloud 1126 may tasked with executing at least some of services 1020 of system 1100, including compute service(s) 1116, AI service(s) 1118, and/or visualization service(s) 1120, as described herein. In at least one embodiment, cloud 1126 may perform small and large batch inference (e.g., executing NVIDIA's TENSOR RT), provide an accelerated parallel computing API and platform 1130 (e.g., NVIDIA's CUDA), execute application orchestration system 1128 (e.g., KUBERNETES), provide a graphics rendering API and platform (e.g., for ray-tracing, 2D graphics, 3D graphics, and/or other rendering techniques to produce higher quality cinematics), and/or may provide other functionality for system 1100.

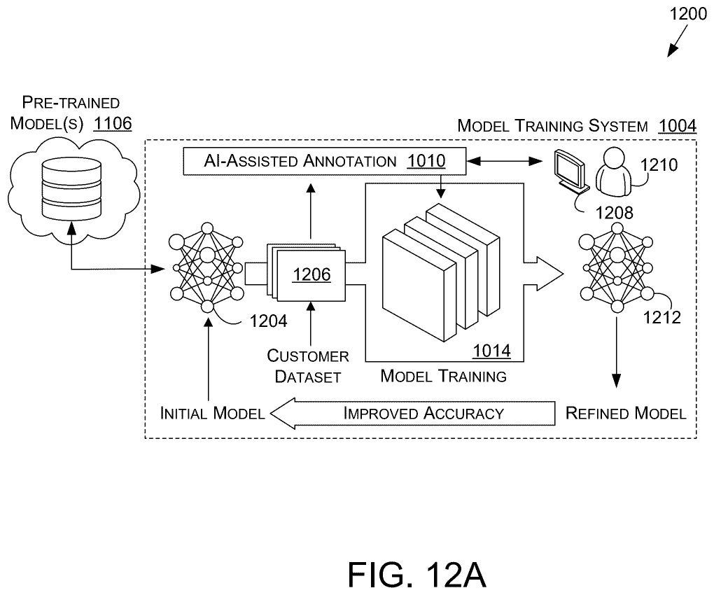

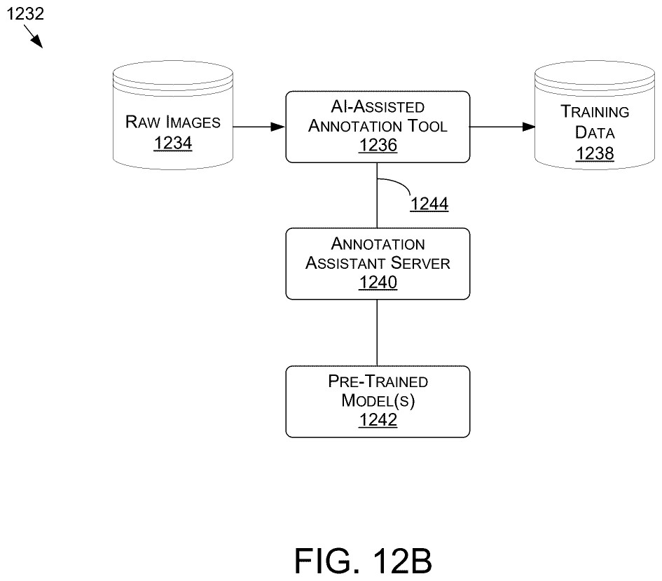

FIG. 12A illustrates a data flow diagram for a process 1200 to train, retrain, or update a machine learning model, in accordance with at least one embodiment. In at least one embodiment, process 1200 may be executed using, as a non-limiting example, system 1100 of FIG. 11. In at least one embodiment, process 1200 may leverage services and/or hardware as described herein. In at least one embodiment, refined models 1212 generated by process 1200 may be executed by a deployment system for one or more containerized applications in deployment pipelines.

In at least one embodiment, model training 1014 may include retraining or updating an initial model 1204 (e.g., a pre-trained model) using new training data (e.g., new input data, such as customer dataset 1206, and/or new ground truth data associated with input data). In at least one embodiment, to retrain, or update, initial model 1204, output or loss layer(s) of initial model 1204 may be reset, deleted, and/or replaced with an updated or new output or loss layer(s). In at least one embodiment, initial model 1204 may have previously fine-tuned parameters (e.g., weights and/or biases) that remain from prior training, so training or retraining 1014 may not take as long or require as much processing as training a model from scratch. In at least one embodiment, during model training 1014, by having reset or replaced output or loss layer(s) of initial model 1204, parameters may be updated and re-tuned for a new data set based on loss calculations associated with accuracy of output or loss layer(s) at generating predictions on new, customer dataset 1206.

In at least one embodiment, pre-trained models 1206 may be stored in a data store, or registry. In at least one embodiment, pre-trained models 1206 may have been trained, at least in part, at one or more facilities other than a facility executing process 1200. In at least one embodiment, to protect privacy and rights of patients, subjects, or clients of different facilities, pre-trained models 1206 may have been trained, on-premise, using customer or patient data generated on-premise. In at least one embodiment, pre-trained models 1106 may be trained using a cloud and/or other hardware, but confidential, privacy protected patient data may not be transferred to, used by, or accessible to any components of a cloud (or other off premise hardware). In at least one embodiment, where pre-trained models 1206 is trained at using patient data from more than one facility, pre-trained models 1206 may have been individually trained for each facility prior to being trained on patient or customer data from another facility. In at least one embodiment, such as where a customer or patient data has been released of privacy concerns (e.g., by waiver, for experimental use, etc.), or where a customer or patient data is included in a public data set, a customer or patient data from any number of facilities may be used to train pre-trained models 1206 on-premise and/or off premise, such as in a datacenter or other cloud computing infrastructure.

In at least one embodiment, when selecting applications for use in deployment pipelines, a user may also select machine learning models to be used for specific applications. In at least one embodiment, a user may not have a model for use, so a user may select a pre-trained model to use with an application. In at least one embodiment, pre-trained model may not be optimized for generating accurate results on customer dataset 1206 of a facility of a user (e.g., based on patient diversity, demographics, types of medical imaging devices used, etc.). In at least one embodiment, prior to deploying a pre-trained model into a deployment pipeline for use with an application(s), pre-trained model may be updated, retrained, and/or fine-tuned for use at a respective facility.

In at least one embodiment, a user may select pre-trained model that is to be updated, retrained, and/or fine-tuned, and this pre-trained model may be referred to as initial model 1204 for a training system within process 1200. In at least one embodiment, a customer dataset 1206 (e.g., imaging data, genomics data, sequencing data, or other data types generated by devices at a facility) may be used to perform model training (which may include, without limitation, transfer learning) on initial model 1204 to generate refined model 1212. In at least one embodiment, ground truth data corresponding to customer dataset 1206 may be generated by training system 1004. In at least one embodiment, ground truth data may be generated, at least in part, by clinicians, scientists, doctors, practitioners, at a facility.

In at least one embodiment, AI-assisted annotation may be used in some examples to generate ground truth data. In at least one embodiment, AI-assisted annotation (e.g., implemented using an AI-assisted annotation SDK) may leverage machine learning models (e.g., neural networks) to generate suggested or predicted ground truth data for a customer dataset. In at least one embodiment, a user may use annotation tools within a user interface (a graphical user interface (GUI)) on a computing device.

In at least one embodiment, user 1210 may interact with a GUI via computing device 1208 to edit or fine-tune (auto)annotations. In at least one embodiment, a polygon editing feature may be used to move vertices of a polygon to more accurate or fine-tuned locations.

In at least one embodiment, once customer dataset 1206 has associated ground truth data, ground truth data (e.g., from AI-assisted annotation, manual labeling, etc.) may be used by during model training to generate refined model 1212. In at least one embodiment, customer dataset 1206 may be applied to initial model 1204 any number of times, and ground truth data may be used to update parameters of initial model 1204 until an acceptable level of accuracy is attained for refined model 1212. In at least one embodiment, once refined model 1212 is generated, refined model 1212 may be deployed within one or more deployment pipelines at a facility for performing one or more processing tasks with respect to medical imaging data.

In at least one embodiment, refined model 1212 may be uploaded to pre-trained models in a model registry to be selected by another facility. In at least one embodiment, this process may be completed at any number of facilities such that refined model 1212 may be further refined on new datasets any number of times to generate a more universal model.

FIG. 12B is an example illustration of a client-server architecture 1232 to enhance annotation tools with pre-trained annotation models, in accordance with at least one embodiment. In at least one embodiment, AI-assisted annotation tool 1236 may be instantiated based on a client-server architecture 1232. In at least one embodiment, AI-assisted annotation tool 1236 in imaging applications may aid radiologists, for example, identify organs and abnormalities. In at least one embodiment, imaging applications may include software tools that help user 1210 to identify, as a non-limiting example, a few extreme points on a particular organ of interest in raw images 1234 (e.g., in a 3D MRI or CT scan) and receive auto-annotated results for all 2D slices of a particular organ. In at least one embodiment, results may be stored in a data store as training data 1238 and used as (for example and without limitation) ground truth data for training. In at least one embodiment, when computing device 1208 sends extreme points for AI-assisted annotation, a deep learning model, for example, may receive this data as input and return inference results of a segmented organ or abnormality. In at least one embodiment, pre-instantiated annotation tools, such as AI-assisted annotation tool 1236 in FIG. 12B, may be enhanced by making API calls (e.g., API Call 1244) to a server, such as an Annotation Assistant Server 1240 that may include a set of pre-trained models 1242 stored in an annotation model registry, for example. In at least one embodiment, an annotation model registry may store pre-trained models 1242 (e.g., machine learning models, such as deep learning models) that are pre-trained to perform AI-assisted annotation on a particular organ or abnormality. These models may be further updated by using training pipelines. In at least one embodiment, pre-installed annotation tools may be improved over time as new labeled data is added.
1. A system, comprising:
   one or more processing units to:
   generate a digital representation of a datacenter;
   specify a configuration to use with the digital representation, the configuration representing parameters of the datacenter at a current point in time or a future point in time;
   execute a simulation of the datacenter using the configuration with the digital representation, the simulation running a workflow representing anticipated requirements of one or more processing jobs to be performed at the current or future point in time; and
   provide, in response to a prompt received to a language model trained with respect to the datacenter, information about the simulation being executed.
2. The system of clause 1, wherein the digital representation is a physical digital twin of the datacenter including a virtual three-dimensional representation of a set of connected functional components of the datacenter.
3. The system of clause 1, wherein the one or more processing units are further to generate a set of configurations, individual configurations of the set representing the datacenter at different points in time with different parameter values.
4. The system of clause 1, wherein the digital representation is generated in a simulation environment or provided using a trained machine learning model.
5. The system of clause 1, wherein the prompt relates to a time to run a job, a time to perform maintenance, a time to perform an update or installation, or an improved approach to processing one or more jobs in the datacenter.
6. The system of clause 1, wherein the one or more processing units are further to collect telemetry data for the datacenter during operation and update at least one of the digital representation, the configuration, or the language model.
7. The system of clause 1, wherein the workflow further indicates components of the datacenter that are to be used to perform the one or more processing jobs.
8. The system of clause 1, wherein a trained model is used to infer a number of potential optimizations of the datacenter to perform the one or more processing jobs, and wherein the information about the simulation includes information for at least a subset of the potential optimizations tested as part of the simulation.
9. The system of clause 8, wherein the language model is further able to allow a user to specify one or more criteria to use for inferring the potential optimizations.
10. A simulation environment, comprising:
   one or more processors to execute a simulation of a datacenter using a digital representation of the datacenter and a configuration specifying a state of the datacenter for at least one point in time, the one or more processors further allowing for querying of a language model, trained with respect to the datacenter, to provide information regarding one or more actions to be performed in the datacenter based on information from the simulation.
11. The simulation environment of clause 10, wherein the information includes at least one of health status, telemetry data, optimization results, or test results for performing one or more jobs in the datacenter.
12. The simulation environment of clause 10, wherein the digital representation of the datacenter comprises a set of three-dimensional (3D) objects and their locations in the datacenter, including time-specific connections between the 3D objects.
13. The simulation environment of clause 10, wherein one or more potential optimizations of the datacenter are inferred using a trained AI model, and wherein at least a subset of the optimizations are tested during the simulation.
14. The simulation environment of clause 10, wherein the querying includes submission or generation of a prompt relating to a time to run a job, a time to perform maintenance, a time to perform an update or installation, or an improved approach to processing one or more jobs in the datacenter.
15. The simulation environment of clause 10, wherein the information regarding the one or more actions is further used to fine-tune the language model.
16. The simulation environment of clause 10, wherein the simulation environment is to be used to simulate at least one of:
   a system for testing or validating autonomous machine applications;
   a system for performing digital twin operations;
   a system for performing light transport simulation;
   a system for rendering graphical output;
   a system for performing deep learning operations;
   a system for performing generative AI operations using a large language model (LLM);
   a system implemented using an edge device;
   a system for generating or presenting virtual reality (VR) content;
   a system for generating or presenting augmented reality (AR) content;
   a system for generating or presenting mixed reality (MR) content;
   a system incorporating one or more Virtual Machines (VMs);
   a system implemented at least partially in a datacenter;
   a system for performing hardware testing using simulation;
   a system for performing generative operations using a language model (LM);
   a system for synthetic data generation;
   a collaborative content creation platform for 3D assets; or
   a system implemented at least partially using cloud computing resources.
17. At least one processor, comprising:
   one or more processing units to:
   generate a digital representation of a datacenter;
   specify a configuration to use with the digital representation, the configuration representing parameters of the datacenter at a current point in time or a future point in time; execute a simulation of the datacenter using the configuration with the digital representation, the simulation running a workflow representing anticipated requirements of one or more processing jobs to be performed at the current or future point in time; and
   provide, in response to a prompt received to a language model trained with respect to the datacenter, information about the simulation being executed.
18. The at least one processor of clause 17, wherein the digital representation is a physical digital twin of the datacenter including a virtual three-dimensional representation of a set of connected functional components of the datacenter.
19. The at least one processor of clause 17, wherein the at least one processor is further to generate a set of configurations, individual configurations of the set representing the datacenter at different points in time with different parameter values.
20. The at least one processor of clause 17, wherein at least one processor is contained in:
   a system for performing simulation operations;
   a system for performing simulation operations to test or validate autonomous machine applications;
   a system for performing digital twin operations;
   a system for performing light transport simulation;
   a system for rendering graphical output;
   a system for performing deep learning operations;
   a system for performing generative AI operations using a large language model (LLM);
   a system implemented using an edge device;
   a system for generating or presenting virtual reality (VR) content;
   a system for generating or presenting augmented reality (AR) content;
   a system for generating or presenting mixed reality (MR) content;
   a system incorporating one or more Virtual Machines (VMs);
   a system implemented at least partially in a datacenter;
   a system for performing hardware testing using simulation;
   a system for performing generative operations using a language model (LM);
   a system for synthetic data generation;
   a collaborative content creation platform for 3D assets; or
   a system implemented at least partially using cloud computing resources.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

All references, including publications, patent applications, and patents, cited herein are hereby incorporated by reference to same extent as if each reference were individually and specifically indicated to be incorporated by reference and were set forth in its entirety herein.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system, comprising:
one or more processing units to:
generate a digital representation of a datacenter;
specify a configuration to use with the digital representation, the configuration representing parameters of the datacenter at a current point in time or a future point in time;
execute a simulation of the datacenter using the configuration with the digital representation, the simulation running a workflow representing anticipated requirements of one or more processing jobs to be performed at the current or future point in time; and
provide, in response to a prompt received to a language model trained with respect to the datacenter, information about the simulation being executed.

2. The system of claim 1, wherein the digital representation is a physical digital twin of the datacenter including a virtual three-dimensional representation of a set of connected functional components of the datacenter.

3. The system of claim 1, wherein the one or more processing units are further to generate a set of configurations, individual configurations of the set representing the datacenter at different points in time with different parameter values.

4. The system of claim 1, wherein the digital representation is generated in a simulation environment or provided using a trained machine learning model.

5. The system of claim 1, wherein the prompt relates to a time to run a job, a time to perform maintenance, a time to perform an update or installation, or an improved approach to processing one or more jobs in the datacenter.

6. The system of claim 1, wherein the one or more processing units are further to collect telemetry data for the datacenter during operation and update at least one of the digital representation, the configuration, or the language model.

7. The system of claim 1, wherein the workflow further indicates components of the datacenter that are to be used to perform the one or more processing jobs.

8. The system of claim 1, wherein a trained model is used to infer a number of potential optimizations of the datacenter to perform the one or more processing jobs, and wherein the information about the simulation includes information for at least a subset of the potential optimizations tested as part of the simulation.

9. The system of claim 8, wherein the language model is further able to allow a user to specify one or more criteria to use for inferring the potential optimizations.

10. A simulation environment, comprising:
one or more processors to execute a simulation of a datacenter using a digital representation of the datacenter and a configuration specifying a state of the datacenter for at least one point in time, the one or more processors further allowing for querying of a language model, trained with respect to the datacenter, to provide information regarding one or more actions to be performed in the datacenter based on information from the simulation.

11. The simulation environment of claim 10, wherein the information includes at least one of health status, telemetry data, optimization results, or test results for performing one or more jobs in the datacenter.

12. The simulation environment of claim 10, wherein the digital representation of the datacenter comprises a set of three-dimensional (3D) objects and their locations in the datacenter, including time-specific connections between the 3D objects.

13. The simulation environment of claim 10, wherein one or more potential optimizations of the datacenter are inferred using a trained AI model, and wherein at least a subset of the optimizations are tested during the simulation.

14. The simulation environment of claim 10, wherein the querying includes submission or generation of a prompt relating to a time to run a job, a time to perform maintenance, a time to perform an update or installation, or an improved approach to processing one or more jobs in the datacenter.

15. The simulation environment of claim 10, wherein the information regarding the one or more actions is further used to fine-tune the language model.

16. The simulation environment of claim 10, wherein the simulation environment is to be used to simulate at least one of:
a system for testing or validating autonomous machine applications;
a system for performing digital twin operations;
a system for performing light transport simulation;
a system for rendering graphical output;
a system for performing deep learning operations;
a system for performing generative AI operations using a large language model (LLM);
a system implemented using an edge device;
a system for generating or presenting virtual reality (VR) content;
a system for generating or presenting augmented reality (AR) content;
a system for generating or presenting mixed reality (MR) content;
a system incorporating one or more Virtual Machines (VMs);
a system implemented at least partially in a datacenter;
a system for performing hardware testing using simulation;
a system for performing generative operations using a language model (LM);
a system for synthetic data generation;
a collaborative content creation platform for 3D assets; or
a system implemented at least partially using cloud computing resources.

17. At least one processor, comprising:
one or more processing units to:
generate a digital representation of a datacenter;
specify a configuration to use with the digital representation, the configuration representing parameters of the datacenter at a current point in time or a future point in time;
execute a simulation of the datacenter using the configuration with the digital representation, the simulation running a workflow representing anticipated requirements of one or more processing jobs to be performed at the current or future point in time; and
provide, in response to a prompt received to a language model trained with respect to the datacenter, information about the simulation being executed.

18. The at least one processor of claim 17, wherein the digital representation is a physical digital twin of the datacenter including a virtual three-dimensional representation of a set of connected functional components of the datacenter.

19. The at least one processor of claim 17, wherein the at least one processor is further to generate a set of configurations, individual configurations of the set representing the datacenter at different points in time with different parameter values.

20. The at least one processor of claim 17, wherein at least one processor is contained in:
a system for performing simulation operations;
a system for performing simulation operations to test or validate autonomous machine applications;
a system for performing digital twin operations;
a system for performing light transport simulation;
a system for rendering graphical output;
a system for performing deep learning operations;
a system for performing generative AI operations using a large language model (LLM);
a system implemented using an edge device;
a system for generating or presenting virtual reality (VR) content;
a system for generating or presenting augmented reality (AR) content;
a system for generating or presenting mixed reality (MR) content;
a system incorporating one or more Virtual Machines (VMs);
a system implemented at least partially in a datacenter;
a system for performing hardware testing using simulation;
a system for performing generative operations using a language model (LM);
a system for synthetic data generation;
a collaborative content creation platform for 3D assets; or
a system implemented at least partially using cloud computing resources.
